(19) United States
(12) Patent Application Publication
(10) Pub. No.: US 2025/0374792 A1
(43) Pub. Date: Dec. 4, 2025

(54) DISPLAY DEVICE AND DISPLAY PANEL

(71) Applicant: LG Display Co., Ltd., Seoul (KR)

(72) Inventors: JaeGyun LEE, Paju-si (KR); Ruda RHE, Paju-si (KR); SuChang AN, Paju-si (KR); JiHyun JUNG, Paju-si (KR); Hyangmyoung GWON, Paju-si (KR)

(73) Assignee: LG Display Co., Ltd., Seoul (KR)

(21) Appl. No.: 19/193,614

(22) Filed: Apr. 29, 2025

(30) Foreign Application Priority Data
May 28, 2024 (KR) 10-2024-0069324

(51) Int. Cl. H10K 59/40; G06F 3/041; H10H 29/80; H10H 29/853; H10K 59/80

(52) U.S. Cl. CPC H10K 59/40; H10H 29/8321; H10H 29/853; H10K 59/80521; H10K 59/873; G06F 3/0412

(57) ABSTRACT

A display device and a display panel are discussed. The display device can include a substrate, a bank disposed on the substrate, a cathode electrode disposed on the bank, an encapsulation layer disposed on the cathode electrode, a touch insulation layer disposed on the encapsulation layer, and a touch metal disposed on the touch insulation layer. The display device provides an advantage of preventing or reducing the formation of parasitic capacitance in the touch metal through a trench structure of the bank.

### CROSS REFERENCE TO RELATED APPLICATION

This application claims priority to Korean Patent Application No. 10-2024-0069324, filed on May 28, 2024 in the Korean Intellectual Property Office, the entire contents of which are hereby expressly incorporated by reference for all purposes into the present application.

### BACKGROUND

### Technical Field

The present disclosure relates to electronic devices, and more specifically, for example, without limitation, to display devices and display panels capable of reducing undesirable parasitic capacitance formed between a touch electrode and another electrode when a touch input is performed.

### Discussion of the Related Art

In today's information society, display devices for presenting images or visual information to users are becoming increasingly important. The need for such display devices has caused display technology to be rapidly developed, and recently, various types of display devices, such as a liquid crystal display (LCD) device, a plasma display device, a quantum-dot (QD) light emitting display device, an organic light emitting display (e.g., OLED) device, an inorganic light emitting display device, and the like, have been developed and widely used.

Among such display devices, as display devices equipped with a more convenient user interface compared with general input devices, such as buttons, keyboards, mice, and the like, touch display devices capable of providing a touch-based input function or technique that enables users to input information or commands intuitively and conveniently are increasingly popular.

To enable a touch display device to provide a touch-based input interface, the touch display device is needed to have a capability accurately to detect the presence or absence of a touch from a user and detect a coordinate of the touch.

To provide such a touch-based input interface, a touch display device can include a touch panel in which a plurality of touch electrodes and a plurality of touch lines are disposed, and the touch electrodes and the touch lines can be arranged in a complicated structure. Such a complicated arrangement can cause unnecessary parasitic capacitance to be formed between the touch electrodes, between touch lines, and between the touch electrodes and touch lines. The formation of parasitic capacitance can be different depending on a structure in which touch electrodes and touch lines are disposed in the touch panel or a display panel in which the touch panel is integrated.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventors of the present application have realized that parasitic capacitance generated by the touch electrodes and/or the touch lines can reduce the accuracy of touch sensing. Therefore, a need has arisen for a technology capable of minimizing or preventing the formation of parasitic capacitance between touch electrodes and/or touch lines.

To address these issues and other limitations associated with the related art, one or more aspects of the present disclosure can provide a display device capable of reducing undesirable parasitic capacitance formed between a touch electrode and another electrode (e.g., a cathode electrode of a light emitting element) when a touch input is performed.

One or more aspects of the present disclosure can provide a display device capable of preventing/minimizing the formation of undesirable parasitic capacitance between a touch electrode and another electrode (e.g., a cathode electrode of a light emitting element) when a touch input is performed.

According to one or more example embodiments of the present disclosure, a display device can include a substrate, a bank disposed on the substrate and including a first trench, a cathode electrode disposed on the bank, an encapsulation layer disposed on the cathode electrode, a touch insulating layer disposed on the encapsulation layer, and at least one touch metal disposed on the touch insulating layer and overlapping with the first trench.

According to one or more example embodiments of the present disclosure, a display device can include a substrate, a bank disposed on the substrate, a cathode electrode disposed on the bank, an encapsulation layer disposed on the cathode electrode, a touch insulation layer disposed on the encapsulation layer, and at least one touch metal disposed on the touch insulation layer. The cathode electrode can include an opening in at least a portion of an area vertically overlapping with the at least one touch metal.

According to one or more example embodiments of the present disclosure, a display device can include a substrate, a bank disposed on the substrate, a cathode electrode disposed on the bank, an encapsulation layer disposed on the cathode electrode, a touch insulation layer disposed on the encapsulation layer, and at least one touch metal disposed on the touch insulation layer. The encapsulation layer can have a first thickness in a first area not overlapping with the at least one touch metal, and have a second thickness greater than the first thickness in a second area overlapping with the at least one touch metal.

According to one or more example embodiments of the present disclosure, a display panel can include a substrate, a bank disposed on the substrate and including a first trench, a cathode electrode disposed on the bank, an encapsulation layer disposed on the cathode electrode, a touch insulating layer disposed on the encapsulation layer, and at least one touch metal disposed on the touch insulating layer and overlapping with the first trench.

According to one or more example embodiments of the present disclosure, a display panel can include a substrate, a bank disposed on the substrate, a cathode electrode disposed on the bank, an encapsulation layer disposed on the cathode electrode, a touch insulation layer disposed on the encapsulation layer, and at least one touch metal disposed on the touch insulation layer. The cathode electrode can include an opening in at least a portion of an area vertically overlapping with the at least one touch metal.

According to one or more example embodiments of the present disclosure, a display panel can include a substrate, a bank disposed on the substrate, a cathode electrode disposed on the bank, an encapsulation layer disposed on the cathode electrode, a touch insulation layer disposed on the encapsulation layer, and at least one touch metal disposed on the touch insulation layer. The encapsulation layer can have a first thickness in a first area not overlapping with the at least one touch metal, and have a second thickness greater than the first thickness in a second area overlapping with the at least one touch metal.

According to one or more aspects of the present disclosure, a display device can have a structure capable of reducing, preventing, or eliminating undesirable parasitic capacitance which may be formed between a touch electrode and another electrode (e.g., a cathode electrode of a light emitting element) when a touch input is performed, and thereby, provides an advantage of improving the capability to detect the touch input.

According to one or more aspects of the present disclosure, a display device can have a structure capable of preventing or minimizing undesirable parasitic capacitance from being formed between a touch electrode and another electrode (e.g., a cathode electrode of a light emitting element) when a touch input is performed, and thereby, provides an advantage of improving the capability to detect the touch input.

According to one or more aspects of the present disclosure, a display device can include a touch panel or a display panel where the touch panel is integrated that is configured to reduce or prevent the formation of undesirable parasitic capacitance between conductive elements disposed therein without separate operating or driving for reducing or preventing the parasitic capacitance, and thereby, provides an advantage of reducing or preventing the undesirable parasitic capacitance.

According to one or more aspects of the present disclosure, display devices can provide advantages of reducing power consumption for reducing or preventing parasitic capacitance, and thereby, enabling low-power and high-efficiency touch detection design.

Objects of the present disclosure are not limited to the above-described object, and other objects of the present disclosure not yet described will be more clearly understood by those skilled in the art from the following detailed description.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example display device according to aspects of the present disclosure;

FIG. 2 illustrates an example display panel according to aspects of the present disclosure;

FIG. 3 is an example cross-sectional view of the display panel according to aspects of the present disclosure;

FIG. 4 is an example cross-sectional view of an area of the display device in which a touch metal is disposed according to aspects of the present disclosure;

FIG. 5A is an example plan view of a portion of the display device according to aspects of the present disclosure;

FIGS. 5B and 5C are example cross-sectional views of the display device taken along line A-A′ of FIG. 5A;

FIG. 6A is an example plan view of a portion of the display device according to aspects of the present disclosure;

FIG. 6B is an example cross-sectional view of the display device taken along line B-B′ of FIG. 6A;

FIG. 7A is an example plan view of a portion of the display device according to aspects of the present disclosure;

FIGS. 7B to 7D are example cross-sectional views of the display device taken along line C-C′ of FIG. 7A;

FIG. 8A is an example plan view of a portion of the display device according to aspects of the present disclosure; and

FIGS. 8B to 8D are example cross-sectional views of the display device taken along line D-D′ of FIG. 8A.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Reference will now be made in detail to example embodiments of the present disclosure, examples of which can be illustrated in the accompanying drawings. In the following description, the structures, embodiments, implementations, methods and operations described herein are not limited to the specific example(s) or aspect(s) set forth herein and can be changed as is known in the art, unless otherwise specified. Like reference numerals designate like elements throughout, unless otherwise specified. Names of the respective elements used in the following explanations are selected only for convenience of writing the specification and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted or may be briefly provided.

Where the terms “include,” “have,” “comprise,” “contain,” “constitute,” “make up of,” “formed of,” and “consist of” and the like are used, one or more other elements can be added unless the term, such as “only,” is used. An element described in the singular form is intended to include a plurality of elements, and vice versa, unless the context clearly indicates otherwise.

The shapes, sizes, dimensions (e.g., length, width, height, thickness, radius, diameter, area, etc.), ratios, angles, numbers of elements, and the like illustrated in the accompanying drawings for describing the example embodiments of the present disclosure are merely examples, and the present disclosure is not limited thereto. Like reference numerals generally denote like elements throughout the specification.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Although the terms “first,” “second,” “A”, “B”, “(a)”, or “(b)”, and the like can be used herein to describe various elements, these elements should not be interpreted to be limited by these terms as they are not used to define a particular order or precedence. These terms are used only to distinguish one element from another; thus, related elements should not be interpreted to be limited by these terms as they are not used to define a particular order or precedence.

Further, the expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers “disposed” or “interposed” between the elements or layers, unless otherwise specified. Further, the another element can be included in one or more of the two or more elements connected, combined, coupled, or contacted (to) one another.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers “disposed” or “interposed” between the elements or layers, unless otherwise specified.

Spatially relative terms, such as “under,” “below,” “beneath”, “lower,” “over,” “upper” and the like, can be used herein for ease of description to describe one element or feature's relationship to another element(s) or feature(s) as illustrated in the figures. It will be understood that the spatially relative terms can encompass different orientations of an element in use or operation in addition to the orientation depicted in the figures. For example, if an element in the figures is inverted, elements described as “below” or “beneath” other elements or features would then be oriented “over” the other elements or features. Thus, the exemplary term “below” can encompass both an orientation of below and above. Similarly, the exemplary term “above” or “over” can encompass both an orientation of “above” and “below”.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In describing a temporal relationship, when the temporal order is described as, for example, “after,” “subsequent,” “next,” or “before,” a case which is not continuous can be included unless a more limiting term, such as “just,” “immediate(ly),” or “direct(ly),” is used.

In construing an element, the element is to be construed as including an error or tolerance range even where no explicit description of such an error or tolerance range is provided.

Further, the term “may” fully encompasses all the meanings of the term “can” and vice versa.

The term “at least one” should be understood as including any or all combinations of one or more of the associated listed items. For example, the meaning of “at least one of a first element, a second element, and a third element” encompasses the combination of all three listed elements, combinations of any two of the three elements, as well as each individual element, the first element, the second element, and the third element. The expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

In addition, for convenience of description, a scale in which each of elements is illustrated in the accompanying drawings can differ from an actual scale. Thus, the illustrated elements are not limited to the specific scale in which they are illustrated in the drawings.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

The respective features of various embodiments according to the present disclosure can be partially or entirely joined or combined and technically variably related or operated, and the embodiments can be implemented independently or in combination.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein.

In the aspects of the present disclosure, a source electrode and a drain electrode are distinguished from each other, for convenience of description. However, the source electrode and the drain electrode are used interchangeably. The source electrode can be the drain electrode, and the drain electrode can be the source electrode. Further, the source electrode in any one aspect of the present disclosure can be the drain electrode in another aspect of the present disclosure, and the drain electrode in any one aspect of the present disclosure can be the source electrode in another aspect of the present disclosure.

Hereinafter, various example embodiments of the present disclosure will be described in detail with reference to the accompanying drawings. All the components of each display device and each display panel according to all embodiments of the present disclosure are operatively coupled and configured. In addition, for convenience of description, a scale in which each of elements is illustrated in the accompanying drawings can differ from an actual scale. Thus, the illustrated elements are not limited to the specific scale in which they are illustrated in the drawings.

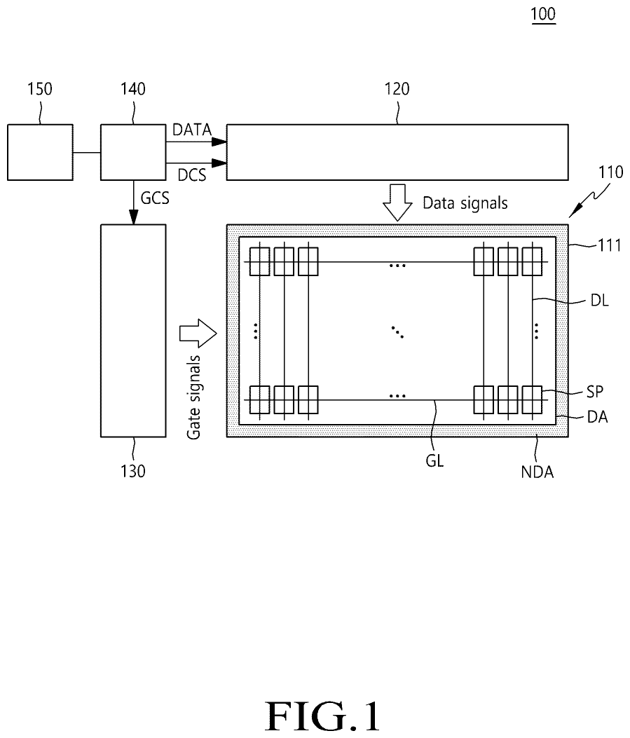

FIG. 1 illustrates an example display device 100 according to aspects of the present disclosure.

Referring to FIG. 1, in one or more example embodiments, the display device 100 can include a display panel 110 and a display driving circuit, as elements for display images. The display driving circuit can be a circuit for driving the display panel 110. The display driving circuit can include, for example, a data driving circuit 120, a gate driving circuit 130, and a controller 140. However, aspects of the present disclosure are not limited to such specific structures. For example, the display driving circuit can further include other circuit components.

The display panel 110 can include a substrate 111 and a plurality of subpixels SP disposed on the substrate 111.

The substrate 111 can include a display area DA where an image can be displayed and a non-display area NDA where an image may not be displayed. The non-display area NDA can surround the display area DA entirely or only in part(s).

The display area DA can also be referred to as an active area. For example, a plurality of subpixels SP for displaying images can be disposed in the display area DA. The non-display area NDA can be an area outside of the display area DA. For example, the non-display area NDA can be an area adjacent to the display area DA. Further, the non-display area NDA can be an area disposed adjacent to the display area DA and configured to surround the display area DA. The non-display area NDA can also be referred to as a non-active area or a bezel (or a bezel area). The non-display area NDA can include a pad area located outside of (e.g., spaced apart from) the display area DA in a column direction. For example, the pad area can be a portion of the non-display area NDA.

For example, the non-display area NDA can include a first non-display area, a second non-display area, a third non-display area, and a fourth non-display area. The first non-display area can be located outside of the display area DA in the column direction. The second non-display area can be located outside of the display area DA in a row direction. The third non-display area can be located outside of the display area DA in the column direction and located opposite to the first non-display area. The fourth non-display area can be located outside of the display area DA in the row direction and located opposite to the second non-display area. The first non-display area among the first to fourth non-display areas can include a pad area to which a driving circuit is connected or bonded. The second to fourth non-display areas that do not include the pad area among the first to fourth non-display areas can have a very small size, but aspects of the present disclosure are not limited thereto.

In one or more aspects, a boundary area between the display area DA and the non-display area NDA can be bent, and in this structure, the non-display area NDA can be located under the display area DA.

In these implementations, when a user views the display device 100 in front thereof, all or most of the non-display area NDA may not be visible to the user. However, aspects of the present disclosure are not limited thereto.

In one or more aspects, the display device 100 herein can be a self-emission display device in which light is emitted from the display panel 110 itself. However, aspects of the present disclosure are not limited thereto. In an example where the display device 100 is a self-emission display device, each of the plurality of subpixels SP included in the display device 100 can include a light emitting element such as an organic light emitting diode, an inorganic light emitting diode, a quantum dot light emitting diode, a micro light emitting diode, a mini light emitting diode, or the like.

Each of the plurality of subpixels SP is a minimum unit which configures the display area and n subpixels SP form one pixel. Each of the plurality of subpixels SP can emit light having different wavelengths from each other. The plurality of subpixels can include first to third subpixels which emit different color light from each other. Each pixel P can be divided into a red subpixel, a green subpixel, and a blue subpixel, for color rendering. Each pixel P can further include a white subpixel. The plurality of subpixels SP can be variously modified in colors and configurations, as necessary. However, the present disclosure is not limited thereto.

For example, the plurality of subpixels SP can include red, green, and blue subpixels, in which the red, green, and blue subpixels can be disposed in a repeated manner. Alternatively, the plurality of subpixels SP can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device disclosures.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

In one or more aspects, the display device 100 can be an organic light emitting display device in which the light emitting element is implemented using an organic light emitting diode (OLED). In one or more aspects, the display device 100 can be an inorganic light emitting display device in which the light emitting element is implemented using an inorganic material-based light emitting diode. In one or more aspects, the display device 100 can be a quantum dot display device in which the light emitting element is implemented using quantum dots, which are self-emission semiconductor crystals. In one or more aspects, the display device 100 can be a micro light emitting diode (LED) display device or a mini LED display device in which the light emitting element is implemented using a micro LED or a mini LED. However, aspects of the present disclosure are not limited thereto.

The structure of each of the plurality of subpixels SP can depend on types of display device 100. In an example where the display device 100 is a self-emission display device including self-emission subpixels SP, each subpixel SP can include a self-emission light emitting element, one or more transistors, and one or more capacitors. However, aspects of the present disclosure are not limited thereto.

Each of the plurality of subpixels SP can include a pixel circuit. For example, the pixel circuit of each of the plurality of subpixels can include a capacitor, at least one thin film transistor, and a light emitting element. For example, the at least one thin film transistor can include a driving transistor, a first switching transistor, and a second switching transistor. In addition, the light emitting element can include a first electrode/a second electrode (or anode electrode, pixel electrode), an inorganic light emitting layer (or organic light emitting layer), and a second electrode/a first electrode (or cathode electrode, common electrode). However, the pixel circuit of each of the plurality of subpixels are not limited thereto, each of the plurality of subpixels can further include a compensation circuit. In this case, each of the plurality of subpixels can have various structures such as 4T2C, 5T2C, 6T1C, 6T2C, 7T1C, 7T2C, and the like.

Various types of signal lines for driving a plurality of subpixels SP can be disposed on the substrate 111 of the display panel 110.

The various types of signal lines can include, for example, a plurality of data lines DL for carrying data signals (which can be referred to as data voltages or image signals), a plurality of gate lines GL for carrying gate signals (which can be referred to as scan signals), and the like.

In one or more aspects, the plurality of data lines DL and the plurality of gate lines GL can intersect one another. Each of the plurality of data lines DL can be configured to extend in the column direction, and each of the plurality of gate lines GL can be configured to extend in the row direction. The column direction and the row direction defined herein can be relative directions. For example, the column direction and the row direction can be the row direction and the column direction, respectively, depending on a viewpoint from which a user views the display device 100. Hereinafter, for convenience of explanation, discussions can be provided based on examples where each of a plurality of data lines DL is disposed in the column direction, and each of a plurality of gate lines GL is disposed in the row direction. However, aspects of the present disclosure are not limited thereto. For example, an angle between the row direction and the column direction can be 90 degrees or can be an angle different from 90 degrees. For convenience of description, the row direction can be described as a first direction, and the column direction can be described as a second direction. However, aspects of the present disclosure are not limited thereto, the column direction can be described as a first direction, and the row direction can be described as a second direction.

The data driving circuit 120 can be a circuit for driving a plurality of data lines DL and can output data signals to the plurality of data lines DL.

The data driving circuit 120 can receive image data DATA in a digital form from the controller 140, and convert the received image data DATA into data signals in an analog form, and output converted data signals to the plurality of data lines DL.

In one or more aspects, the data driving circuit 120 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

The data driving circuit 120 can be disposed in, and/or electrically connected to, but not limited to, only one side or edge (e.g., an upper portion or a lower portion) of the display panel 110. In one or more aspects, the data driving circuit 120 can be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 can be connected to the outside, located outside, or located at a periphery, of the display area DA of the display panel 110, or be disposed in the display area DA of the display panel 110.

The gate driving circuit 130 can be a circuit configured to drive a plurality of gate lines GL and can output gate signals to the plurality of gate lines GL.

The gate driving circuit 130 can receive not only various types of gate driving control signals GCS, but a first gate voltage corresponding to a turn-on level voltage and a second gate voltage corresponding to a turn-off level voltage. Thereby, the gate driving circuit 130 can generate gate signals each including a first period having the first gate voltage and a second period having the second gate voltage during a predefined time (e.g., one frame period) and supply the generated gate signals to the plurality of gate lines GL. For example, the turn-on level voltage can be a high level voltage and the turn-off level voltage can be a low level voltage. In another example, the turn-on level voltage can be a low level voltage and the turn-off level voltage can be a high level voltage.

In one or more aspects, the gate driving circuit 130 included in the display device 100 can be embedded into the display panel 110 by a gate-in-panel (GIP) technique. However, aspects of the present disclosure are not limited thereto. In an example where the gate driving circuit 130 is implemented by the gate-in-panel (GIP) technique, the gate driving circuit 130 can be disposed on the substrate 111 of the display panel 110 during the manufacturing process of the display panel 110 or display device 100.

For example, the gate driving circuit 130 can be disposed in the non-display area NDA of the display panel 110.

In one or more aspects, the gate driving circuit 130 can be disposed in the display area DA of the display panel 110. In this implementation, for example, the gate driving circuit 130 can be disposed in, and/or electrically connected to, but not limited to, a first area (e.g., a left area or a right area) of the display area DA of the display panel 110. In another example, the gate driving circuit 130 can be disposed in, and/or electrically connected to, but not limited to, a first area (e.g., a left area or a right area) and a second area (e.g., the right area or the left area) of the display area DA of the display panel 110. In another example, the gate driving circuit 130 can be disposed in, and/or electrically connected to, but not limited to, at least two areas (e.g., a left area and a right area) of the display area DA, or at least two of four areas (e.g., the left area, the right area, an upper area, and a lower area) of the display area DA according to driving schemes, panel design schemes, or the like.

In an example where the gate driving circuit 130 is disposed in the display area DA of the display panel 110, the gate driving circuit 130 can vertically overlap with one or more subpixels SP disposed in the display area DA. In this implementation, the gate driving circuit 130 can vertically overlap with one or more light emitting elements and one or more transistors included in one or more subpixels SP disposed in the display area DA. The gate driving circuit 130 can vertically overlap with a plurality of light emitting elements and a plurality of transistors included in a plurality of subpixels SP disposed in the display area DA. The gate driving circuit 130 can include a plurality of transistors. Each of the plurality of transistors included in the gate driving circuit 130 can include an active layer including a first semiconductor material, and each of the plurality of transistors included in the subpixels SP disposed in the display area DA can include an active layer including a second semiconductor material. For example, the first semiconductor material and the second semiconductor material can be the same. In another example, the first semiconductor material and the second semiconductor material can be different.

Any one of the first semiconductor material and the second semiconductor material can include an oxide semiconductor material, amorphous semiconductor material, or polycrystalline semiconductor material, but is not limited thereto.

The oxide semiconductor material can have an excellent effect of preventing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

For example, the first semiconductor material can be a silicon-based semiconductor material (e.g., a low temperature poly-silicon (LTPS)) and the second semiconductor material can be an oxide semiconductor material, but not limited thereto.

The controller 140 can be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 processes image data DATA input thereto from an outside thereof, to match the size and resolution of the display panel, and then supplies the processed image data DATA to the data driving circuit 120.

The controller 140 generates a gate control signal GCS and a data control signal DCS using timing signals CS input from the outside thereof, for example, a dot clock signal CLK, a date enable signal DE, a horizontal synchronization signal Hsync, and a vertical synchronization signal Vsync. Here, the horizontal synchronization signal is a signal representing a time taken to display one horizontal line of a screen and the vertical synchronization signal is a signal representing a time taken to display a screen of one frame. The data enable signal can correspond to a signal indicating a period for which a data voltage is supplied to the pixel. The controller 140 supplies the gate control signal GCS and the data control signal DCS generated as described above to the gate driving circuit 130 and the data driving circuit 120, respectively, thereby controlling the gate driving circuit 130 and the data driving circuit 120.

The controller 140 can be configured to be coupled with various processors, for example, a microprocessor, a mobile processor, an application processor, etc. in accordance with a device mounted therein.

A host system, which is applied to the controller 140, can be one of a television (TV) system, a set-top box, a navigation system, a personal computer (PC), a home theater system, a mobile appliance, a wearable appliance, and a vehicle system.

The controller 140 can multiply an input frame frequency by i times, thereby controlling operation timings of the display panel drivers at a frame frequency corresponding to an “input frame frequency x i” Hz (i being a positive integer greater than 0). The input frame frequency is 60 Hz in a national television standards committee (NTSC) system, and is 50 Hz in a phase-alternating line (PAL) system.

The controller 140 can generate signals in order to enable each pixel to be driven at various refresh rates. For example, the controller 140 can generate signals associated with driving of each pixel P in order to enable the pixel to be driven in a variable refresh rate (VRR) mode or to be switched between a first refresh rate and a second refresh rate. For example, the controller 140 can drive each pixel at various refresh rates by simply varying a rate of a clock signal, generating a synchronization signal, for generation of a horizontal blank or a vertical blank, or driving the gate driving circuit 130 in a mask manner.

The controller 140 generates the gate control signal GCS for control of an operation timing of the gate driving circuit 130 and the data control signal DCS for control of an operation timing of the data driving circuit 120 based on the timing signals CS received from the host system. The controller 140 synchronizes the gate driving circuit 130 and the data driving circuit 120 with each other by controlling the operation timings of the display panel drivers.

The controller 140 can be implemented in a separate component from the data driving circuit 120, or integrated with the data driving circuit 120, so that the controller 140 and the data driving circuit 120 can be implemented in a single integrated circuit.

The controller 140 can be a timing controller used in the typical display technology or a control apparatus/device capable of additionally performing other control functionalities in addition to the typical function of the timing controller. In one or more embodiments, the controller 140 can be one or more other control circuits different from the timing controller, or a circuit or component in the control apparatus/device. The controller 140 can be implemented using various circuits or electronic components such as an integrated circuit (IC), a field programmable gate array (FPGA), an application specific integrated circuit (ASIC), a processor, and/or the like.

The controller 140 can be mounted on a printed circuit board, a flexible printed circuit, or the like, and can be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces can include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 can include a touch sensor, and a touch sensing circuit configured to sense the touch sensor and detect whether a touch is applied by an object such as a finger, a pen, or the like, or a location of the touch (or touch coordinates).

The touch sensing circuit can include a touch driving circuit configured to drive and sense the touch sensor and generate and output touch sensing data, and a touch controller configured to detect whether a touch is applied or a location of the touch (or touch coordinates) based on the touch sensing data.

The touch sensor can include a plurality of touch electrodes. The touch sensor can further include a plurality of touch lines for electrically connecting the plurality of touch electrodes to the touch driving circuit.

The touch sensor can be disposed outside of the display panel 110 in the form of a touch panel or can be disposed inside of the display panel 110. The touch sensor disposed outside of the display panel 110 can be referred to as an add-on type touch sensor. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on a capacitance between one or more touch electrode and an object such as a finger, a pen, and/or the like. According to the self-capacitance sensing technique, each of a plurality of touch electrodes can serve as both a driving touch electrode and a sensing touch electrode. The touch driving circuit can drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes can be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit can be implemented in separate devices or in a single device. In one or more aspects, the touch driving circuit and the data driving circuit can be implemented in separate devices or in a single device.

The display device 100 can further include a power supply circuit for supplying various types of power to the display driving circuit and/or the touch sensing circuit. The power supply circuit can supply various voltages and power needed for display driving to the display driving circuit or display panel 110.

In one or more aspects, the display device 100 can be a mobile terminal such as a smart phone, a tablet, or the like, or a monitor, a television (TV), or the like. Such apparatuses can be configured in various types, sizes, and shapes. The display device 100 according to aspects of the present disclosure are not limited thereto, and can include various types, sizes, and shapes configured to display information or images. a display device according to the aspects of the present disclosure can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

In one or more aspects, the display device 100 can further include an electronic device such as a camera (e.g., an image sensor), a sensor capable of detecting an object, and the like. For example, the sensor can be a sensor capable of detecting an object or a human body by receiving light such as infrared light, ultrasonic light, ultraviolet light or the like. However, aspects of the present disclosure are not limited to such specific structures.

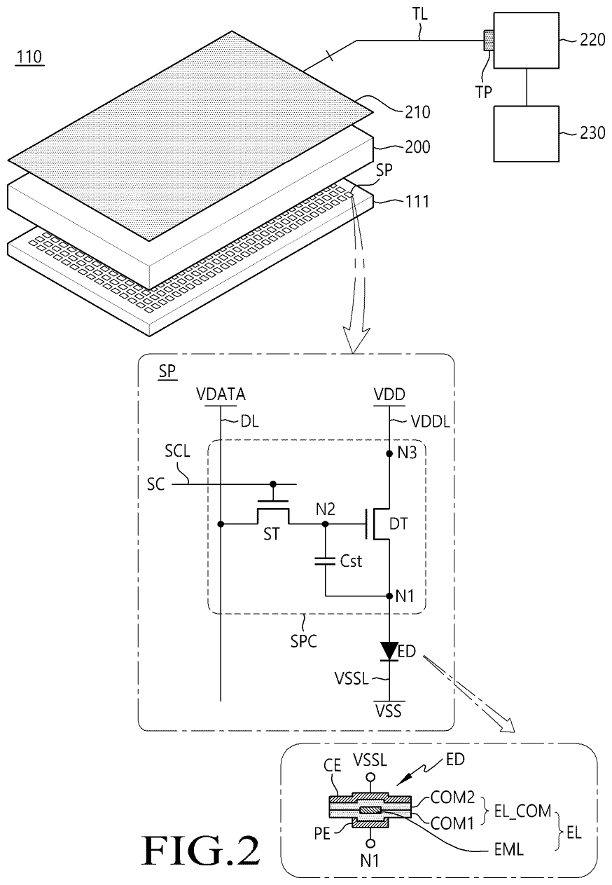

FIG. 2 illustrates an example configuration of the display panel 110 according to aspects of the present disclosure.

Referring to FIG. 2, the display panel 110 can include a substrate 111 on which a plurality of subpixels SP are disposed, and an encapsulation layer 200 over the substrate 111. The encapsulation layer 200 can also be referred to as an encapsulation substrate, an encapsulation stack, or the like.

In an example where the display device 100 is a self-emission display device, each of the plurality of subpixels SP disposed on the substrate 111 can include a light emitting element ED and a subpixel circuit SPC for driving the light emitting element ED.

The subpixel circuit SPC can include a plurality of transistors and at least one capacitor for driving the light emitting element ED, but aspects of the present disclosure are not limited to such specific structures. The subpixel circuit SPC can drive the light emitting element ED by supplying a driving current to the light emitting element ED at a predetermined timing. The light emitting element ED can emit light by being driven by the driving current.

The plurality of transistors can include a driving transistor DT for driving the light emitting element ED and a scan transistor ST configured to be turned on or off by a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst configured to maintain a constant voltage during a display frame or a certain period of the display frame.

To drive at least one subpixel SP, at least one data signal VDATA, which is an image signal, and at least one scan signal SC, which is a gate signal, can be applied to the subpixel SP. Further, a common pixel driving voltage including a first common driving voltage VDD (which can be also referred to as a driving voltage VDD) and a second common driving voltage VSS (which can be also referred to as a base voltage VSS) can be applied to the subpixel SP.

The light emitting element ED can include a pixel electrode PE, an intermediate layer EL, and a common electrode CE. The intermediate layer EL can be disposed between the pixel electrode PE and the common electrode CE.

For example, the pixel electrode PE can be an electrode disposed in each subpixel SP, and the common electrode CE can be an electrode commonly disposed in all or some of a plurality of subpixels SP. For example, the pixel electrode PE can be an anode, and the common electrode CE can be a cathode. In another example, the pixel electrode PE can be a cathode, and the common electrode CE can be an anode. Hereinafter, for convenience of explanation, discussions can be provided based on examples where the pixel electrode PE is an anode, and the common electrode CE is a cathode.

In an example where the light emitting element ED is an organic light emitting diode, the intermediate layer EL can include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 can be referred to as a common intermediate layer EL_COM.

In one or more aspects, the emission layer EML can be disposed in each subpixel SP. The common intermediate layer EL_COM can be commonly disposed across all or some of a plurality of subpixels SP, but aspects of the present disclosure are not limited thereto.

In one or more aspects, the emission layer EML can be disposed in each light emitting area. The common intermediate layer EL_COM can be commonly disposed across all or some of a plurality of light emitting areas and all or some of a plurality of non-light emitting areas, but aspects of the present disclosure are not limited thereto.

For example, the first common intermediate layer COM1 can include a hole injection layer (HIL), an electron blocking layer (EBL), a hole transfer layer (HTL), and/or the like, but aspects of the present disclosure are not limited thereto. The second common intermediate layer COM2 can include an electron transport layer (ETL), a hole blocking layer (HBL), an electron injection layer (EIL), and/or the like, but aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

For example, the common electrode CE can be electrically connected to a base voltage line VSSL. A base voltage VSS, which is a type of common pixel driving voltage, can be applied to the common electrode CE through the base voltage line VSSL. The pixel electrode PE can be electrically connected directly or indirectly (via another transistor) to a first node N1 of a corresponding driving transistor DT of each subpixel SP. Herein, the base voltage VSS can also be referred to as a “low voltage”, or a “low power supply voltage” and the base voltage line VSSL can also be referred to as a “low power supply voltage line”, or a “low voltage line”.

Each light emitting element ED can be configured by the overlap of the pixel electrode PE, the emission layer in the intermediate layer EL, and the common electrode CE. A corresponding light emitting area can be formed by each light emitting element ED. For example, a corresponding light emitting area of each light emitting element ED can include an area at which the pixel electrode PE, the emission layer in the intermediate layer EL, and the common electrode CE overlap with each other.

In one or more aspects, the light emitting element ED can be an organic light emitting diode (OLED), an inorganic light emitting diode (LED), a quantum dot (QD) light emitting element, a micro light emitting diode, a mini light emitting diode, or the like, but aspects of the present disclosure are not limited thereto. For example, in an example where the light emitting element ED is an organic light emitting diode OLED, the intermediate layer EL of the light emitting element ED can be a layer including an organic material.

The driving transistor DT can be a transistor configured to supply a driving current to the light emitting element ED. The driving transistor DT can be connected between a driving voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. A driving voltage VDD through the driving voltage line VDDL can be applied to the third node N3. The driving transistor DT can be connected between the first node N1 and the third node N3.

The second node N2 can be, or correspond to, a gate node of the driving transistor DT, the first node N1 can be, or correspond to, a source node or a drain node of the driving transistor DT, and the third node N3 can be, or correspond to, the drain node or the source node of the driving transistor DT. Hereinafter, for merely convenience of explanation, discussions are provided based on examples where the first, second, and third nodes (N1, N2, and N3) of the driving transistor DT are source, gate, and drain nodes, respectively. However, aspects of the present disclosure are not limited thereto.

The scan transistor ST included in the subpixel circuit SPC illustrated in FIG. 2 can be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst can be an external capacitor intentionally designed to be located or disposed outside of the driving transistor DT, and therefore, be different from an internal capacitor such as a parasitic capacitor (e.g., a Cgs, a Cgd, or the like) that can be formed between the first node N1 and the second node N2 of the driving transistor DT. However, aspects of the present disclosure are not limited thereto.

Each of the driving transistor DT and the scan transistor ST can be an n-type transistor or a p-type transistor, but aspects of the present disclosure are not limited thereto. For example, one of the driving transistor DT and the scan transistor ST can be either an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In this configuration, the area or size of the corresponding light emitting area can increase, and as a result, a corresponding aperture ratio can increase.

In an example where the display panel 110 has the bottom emission structure, the subpixel circuit SPC may not overlap with the light emitting element ED in the vertical direction.

The subpixel circuit SPC can include two transistors (2T: DT and ST) and one capacitor (1C: Cst) (which can be referred to as a “2T1C structure”), and in some implementations, can further include one or more transistors, or further include one or more capacitors.

In one or more aspects, the subpixel circuit SPC can have an 8TIC structure including 8 transistors and 1 capacitor. In one or more aspects, the subpixel circuit SPC can have a 6T2C structure including 6 transistors and 2 capacitor. In one or more aspects, the subpixel circuit SPC can have a 7TIC structure including 7 transistors and 1 capacitor. However, aspects of the present disclosure are not limited to such specific structures.

The types and number of gate signals supplied to a subpixel SP, and/or the types and number of gate lines connected to the subpixel SP can vary depending on a structure of a corresponding subpixel circuit SPC. Further, the types and number of common pixel driving voltages supplied to a subpixel SP can vary depending on a structure of a corresponding subpixel circuit SPC.

Since circuit elements (e.g., a light emitting element ED such as an organic light emitting diode (OLED) including an organic material) in each subpixel SP can be badly damaged by external moisture or oxygen, an encapsulation layer 200 can be disposed in the display panel 110. The encapsulation layer 200 can serve to prevent the external moisture or oxygen from penetrating into the circuit elements (e.g., the light emitting element ED). The encapsulation layer 200 can be disposed in various shapes or configurations to prevent light emitting elements ED from contacting moisture or oxygen. For example, the encapsulation layer 200 can include two or more layers in which organic and inorganic layers are alternately stacked, but aspects of the present disclosure are not limited thereto.

For example, the encapsulation layer 200 can include a first inorganic encapsulation layer, a first organic encapsulation layer, and a second inorganic encapsulation layer stacked sequentially.

Alternatively, the encapsulation layer 200 includes a first inorganic encapsulation layer, a first organic encapsulation layer, a second inorganic encapsulation layer, a second organic encapsulation layer, and a third inorganic encapsulation layer stacked sequentially.

The first inorganic encapsulation layer, the second inorganic encapsulation layer, and the third inorganic encapsulation layer can serve to block the penetration of moisture or oxygen. The first inorganic encapsulation layer, the second inorganic encapsulation layer, and the third inorganic encapsulation layer can be made of an inorganic material, for example, an inorganic material such as silicon nitride (SiNx), silicon oxide (SiOx), or aluminum oxide (AlOx). However, the present disclosure is not limited thereto.

The first organic encapsulation layer is disposed between the first inorganic encapsulation layer and the second inorganic encapsulation layer, and the second organic encapsulation layer is disposed between the second inorganic encapsulation layer and the third inorganic encapsulation layer. The first organic encapsulation layer and the second organic encapsulation layer can each have a larger thickness than each of the first inorganic encapsulation layer, the second inorganic encapsulation layer, and the third inorganic encapsulation layer in order to adsorb or block particles that can be produced during a process of manufacturing the display device. The first organic encapsulation layer and the second organic encapsulation layer can fill cracks that can be formed in the first inorganic encapsulation layer and the second inorganic encapsulation layer. The first organic encapsulation layer and the second organic encapsulation layer can planarize an upper portion of the first inorganic encapsulation layer and an upper portion of the second inorganic encapsulation layer by covering particles on the first inorganic encapsulation layer and the second inorganic encapsulation layer respectively. For example, the first organic encapsulation layer can planarize an upper portion of the first inorganic encapsulation layer by covering particles on the first inorganic encapsulation layer. For example, the second organic encapsulation layer can planarize an upper portion of the second inorganic encapsulation layer by covering particles on the second inorganic encapsulation layer. The first organic encapsulation layer and the second organic encapsulation layer can be made of an organic material, and for example, epoxy polymer, acrylic polymer, or the like can be used. However, the present disclosure is not limited thereto.

Meanwhile, the encapsulation layer 200 is not limited to three or five layers, for example, n layers alternately stacked between inorganic encapsulation layer and organic encapsulation layer (where n is an integer greater than 3) can be included.

In one or more aspects, to detect a touch of a user, the display device 100 can include a touch sensor layer 210 including a plurality of sensor electrodes, a touch driving circuit 220 configured to sense the plurality of sensor electrodes, and a touch controller 230 configured to determine whether a touch is applied or a location of the touch (e.g., touch coordinates) based on the sensing result (e.g., touch sensing data) of the touch driving circuit 220.

The touch sensor layer 210 can be embedded in the display panel 110. For example, the touch sensor layer 210 can be disposed on the encapsulation layer 200 of the display panel 110. The touch sensor layer 210 can be a touch part to which a touch input is applied.

The display panel 110 can include a plurality of touch pads TP to which the touch driving circuit 220 is electrically connected, and a plurality of touch routing lines for electrically connecting the plurality of sensor electrodes included in the touch sensor layer 210 to the plurality of touch pads TP to which the touch driving circuit 220 is connected.

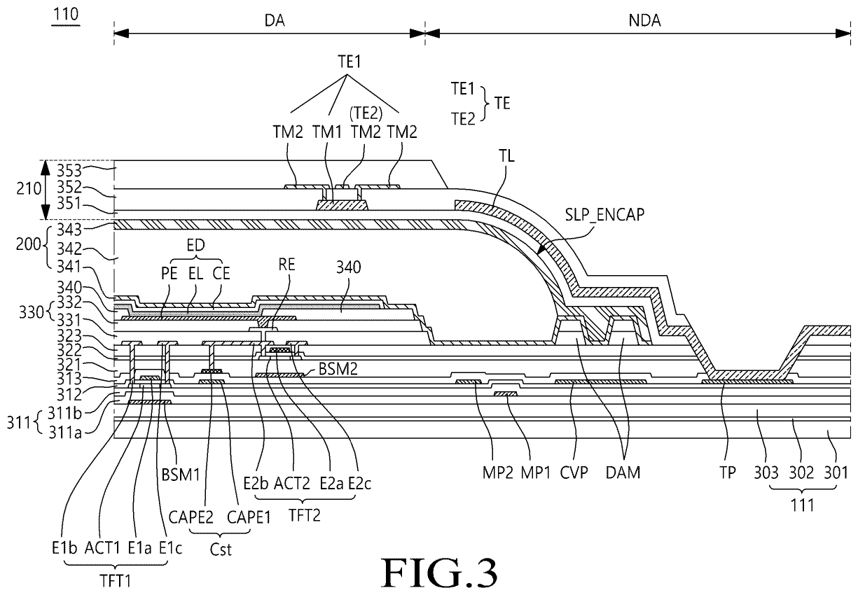

FIG. 3 is an example cross-sectional view of the display panel 110 according to aspects of the present disclosure.

Referring to FIG. 3, in one or more aspects, in terms of stack-up configuration, the display panel 110 can include a transistor part, a light emitting element part, and an encapsulation part. However, aspects of the present disclosure are not limited thereto.

A substrate 111 can be configured in the form of a single layer or multiple layers. In an example where the substrate 111 is configured with multiple layers, the substrate 111 can include a first substrate 301, an intermediate layer 302, and a second substrate 303.

The transistor part can include the substrate 111, one or more insulating layers (311, 312, 313, 321, 322, and/or 323) on the substrate 111, one or more thin film transistors (TFT1 and/or TFT2), at least one storage capacitor Cst, and various electrodes or signal lines.

The thin film transistors (TFT1 and TFT2) included in the transistor part can include a first thin film transistor TFT1 and a second thin film transistor TFT2.

The first transistor TFT1 can include a first active layer ACT1, a first electrode E1a, a second electrode E1b, and a third electrode E1c.

The first electrode E1a can be a gate electrode, the second electrode E1b can be a source electrode or a drain electrode, and the third electrode E1c can be the drain electrode or the source electrode.

The first active layer ACT1 can include a first semiconductor material, but aspects of the present disclosure are not limited thereto. The first transistor TFT1 can be a p-channel transistor or an n-channel transistor, but aspects of the present disclosure are not limited thereto.

The second transistor TFT2 can include a second active layer ACT2, a fourth electrode E2a, a fifth electrode E2b, and a sixth electrode E2c.

The fourth electrode E2a can be a gate electrode, the fifth electrode E2b can be a source electrode or a drain electrode, and the sixth electrode E2c can be the drain electrode or the source electrode.

The second active layer ACT2 can include a second semiconductor material, but aspects of the present disclosure are not limited thereto. The second transistor TFT2 can be a p-channel transistor or an n-channel transistor, but aspects of the present disclosure are not limited thereto.

The storage capacitor Cst can be disposed in various metal layers in the display panel 110. For example, the storage capacitor Cst can include a first capacitor electrode CAPE1 and a second capacitor electrode CAPE2, but not limited thereto.

The light emitting element part can include a plurality of light emitting elements ED disposed on at least one planarization layer 330 (e.g., 331 and/or 332). Each of the light emitting elements ED can include a pixel electrode PE, an intermediate layer EL, and a common electrode CE.

The encapsulation part can include an encapsulation layer 200 on the plurality of light emitting elements ED.

In one or more aspects, the storage capacitor Cst can be configured with the first capacitor electrode CAPE1 and the second capacitor electrode CAPE2.

The transistor part can further include at least one metal pattern (MP1 and/or MP2).

Each of a first metal pattern MP1 and a second metal pattern MP2 can be disposed in the display area DA or the non-display area NDA.

The transistor part can further include a first shield metal BSM1 disposed on the substrate 111.

The transistor part can further include a second shield metal BSM2 disposed on the substrate 111.

The transistor part can further include a common driving voltage layer CVP to which a common driving voltage is applied.

The common driving voltage layer CVP can be disposed in the display area DA or the non-display area NDA.

The planarization layer 330 can be disposed on the first transistor TFT1 and the second transistor TFT2, and can be disposed under the light emitting element ED. The planarization layer 330 can be an organic insulating layer including an organic insulating material. For example, the planarization layer 330 can be formed by using a non-photosensitive organic insulating material such as acryl resin, epoxy resin, phenolic resin, polyamide resin, polyimide resin, polyethylene, or silicon oxycarbide (SiOC) or a photosensitive organic insulating material such as photoacryl, without being limited thereto.

A connection electrode RE can be disposed on the first planarization layer 331. The connection electrode RE can electrically connect the second source electrode E2b of the second transistor TFT2 and the pixel electrode PE.

The connection electrode RE can be electrically connected to the second source electrode E2b of the second transistor TFT2 through a hole of the first planarization layer 331. The second source electrode E2b of the second transistor TFT2 can be electrically connected to the second capacitor electrode CAPE2 of the storage capacitor Cst. The first source electrode E1b and the first drain electrode E1c of the first thin film transistor TFT1 and the second source electrode E2b and the second drain electrode E2d of the second thin film transistor TFT2 can be disposed in the first metal layer and can include the first metal. The first metal and the first metal layer can be referred to as the first source-drain metal and the first source-drain metal layer, but not limited thereto.

The connection electrode RE can be disposed in a second metal layer on the first planarization layer 331 and can include a second metal. The second metal layer and the metal included in the second metal layer can be referred to as a second source-drain metal layer and a second source-drain metal, but not limited thereto.

The second planarization layer 332 can be disposed on the connection electrode RE.

The light emitting area of the light emitting element ED can be formed in an area in which the pixel electrode PE, the intermediate layer EL, and the common electrode CE overlap with, and contact, each other.

The pixel electrode PE can be disposed on the second planarization layer 332. The pixel electrode PE can be electrically connected to the connection electrode RE through a hole of the second planarization layer 332.

A bank 340 can be disposed on the pixel electrode PE. An opening of the bank 340 can be configured to expose a portion of the pixel electrode PE to form the light emitting area. The opening of the bank 340 can overlap with a portion of the pixel electrode PE.

The intermediate layer EL of the light emitting element ED can be disposed on a portion of the pixel electrode PE and the bank 340. The common electrode CE can be disposed on the intermediate layer EL.

The encapsulation part can be located on the light emitting element part and can be disposed on the common electrode CE. The encapsulation part can include an encapsulation layer 200 formed on the common electrode CE.

The encapsulation layer 200 can serve to prevent moisture or oxygen from penetrating into the light emitting element ED. For example, the encapsulation layer 200 can prevent moisture or oxygen from penetrating into an organic material contained in the intermediate layer EL of the light emitting element ED. The encapsulation layer 200 can be configured with a single layer or multiple layers, but aspects of the present disclosure are not limited thereto.

In one or more aspects, the encapsulation layer 200 can include a first encapsulation layer 341, a second encapsulation layer 342, and a third encapsulation layer 343, but aspects of the present disclosure are not limited thereto. For example, the first encapsulating layer 341 and the third encapsulating layer 343 can be inorganic encapsulating layers, and the second encapsulating layer 342 can be an organic encapsulating layer, but aspects of the present disclosure are not limited thereto.

In one or more aspects, a touch sensor can be embedded in the display panel 110. In this implementation, the display panel 110 can include a touch sensor layer 210 disposed on the encapsulation layer 200. The touch sensor layer 210 can be a touch part to which a touch input is applied.

The touch sensor layer 210 can include a plurality of touch electrodes TE serving as the touch sensor. In one or more aspects, to form the plurality of touch electrodes TE, the touch sensor layer 210 can include a touch metal layer in which a plurality of touch metals are disposed.

For example, the touch metal layer can include a first touch metal layer in which a plurality of first touch metals TM1 are disposed, and a second touch metal layer in which a plurality of second touch metals TM2 are disposed. In this example, the touch sensor layer 210 can include a touch interlayer insulation layer 352 between the first touch metal layer and the second touch metal layer.

One of the first touch metal layer and the second touch metal layer can serve as a sensor metal layer, and the other can serve as a bridge metal layer.

In one or more aspects, the first touch metal layer can be a bridge metal layer, and the second touch metal layer can be a sensor metal layer. In this implementation, the plurality of second touch metals TM2 disposed in the second touch metal layer can be sensor metals serving as the touch sensor, and the plurality of first touch metals TM1 disposed in the first touch metal layer can be bridge metals electrically connecting the plurality of second touch metals TM2, which are sensor metals.

In one or more aspects, the first touch metal layer can be a sensor metal layer and the second touch metal layer can be a bridge metal layer. In this implementation, the plurality of first touch metals TM2 disposed in the first touch metal layer can be sensor metals serving as the touch sensor, and the plurality of second touch metals TM1 disposed in the second touch metal layer can be bridge metals electrically connecting the plurality of first touch metals TM1, which are sensor metals.

In one or more aspects, each of the first touch metal layer and the second touch metal layer can serve as both a sensor metal layer and a bridge metal layer. For example, the first touch metal layer can serve as a sensor metal layer and a bridge metal layer, and the second touch metal layer can serve as a sensor metal layer and a bridge metal layer. In this implementation, the plurality of first touch metals TM2 disposed in the first touch metal layer can include sensor metals and bridge metals, and the plurality of second touch metals TM2 disposed in the second touch metal layer can include sensor metals and bridge metals.

The touch sensor layer 210 can include at least one touch interlayer insulating layer.

In one or more aspects, the touch sensor layer 210 can include the touch interlayer insulating layer 352 disposed between the first touch metal layer in which the plurality of first touch metals TM1 are disposed and the second touch metal layer in which the plurality of second touch metals TM2 are disposed. For example, the touch interlayer insulating layer 352 can be an inorganic layer including an inorganic insulating material or an organic layer including an organic insulating material.

In one or more aspects, the touch sensor layer 210 can further include a touch buffer layer 351 between the encapsulation layer 200 and the touch metal layer. The touch buffer layer 351 can be disposed between the encapsulation layer 200 and the first touch metal layer in which the plurality of first touch metals TM1 are disposed. For example, the touch buffer layer 351 may not be disposed according to a design requirement. For example, the touch buffer layer 351 can be an inorganic layer including an inorganic insulating material or an organic layer including an organic insulating material.

The touch buffer layer 351 can prevent a chemical solution (a developer, an etchant or the like) used in a process for manufacturing the touch sensor metal disposed on the touch buffer layer 351, external moisture, etc. from penetrating the light emitting layer including an organic material. Accordingly, the touch buffer layer 351 can prevent damage to the light emitting layer weak against a chemical solution or moisture.

In order to prevent damage to the light emitting layer including an organic material weak against a high temperature, the touch buffer layer 351 is formed of an organic insulating material formable at a low temperature not higher than a predetermined temperature (for example, 100° C.) while having low permittivity of 1 to 3. For example, the touch buffer layer 351 can be formed of an acryl-based material, an epoxy-based material, or a siloxane-based material. The touch buffer layer 351, which is formed of an organic insulating material while having planarization performance, can prevent damage to the encapsulation layer and a fracture phenomenon of the touch sensor metal formed on the touch buffer layer 351 caused by bending of the display device which can be an organic light emitting display device.

In one or more aspects, the touch sensor layer 210 can further include a touch protection layer 353 on the touch metal layer. The touch protection layer 353 can be disposed on the second touch metal layer in which the plurality of second touch metals TM2 are disposed. For example, the touch protection layer 353 can be an inorganic layer including an inorganic insulating material or an organic layer including an organic insulating material. The touch protection layer 353 can extend to an upper portion of a touch line TL as shown in FIG. 3. The touch protection layer 353 can further extend to an upper portion of a touch pad TP.

In one or more aspects, each of the plurality of touch electrodes TE can be configured with at least one of the plurality of second touch metals TM2. Each of the plurality of touch electrodes TE can be an electrode formed from a mesh having a conductive grid structure with one or more openings (hereinafter, which can be referred to as a mesh-type electrode), but aspects of the present disclosure are not limited thereto.

In one or more aspects, the plurality of touch electrodes TE can include at least one first touch electrode TE1 and at least one second touch electrode TE2. In an example where the first touch metal layer is a bridge metal layer and the second touch metal layer is a sensor metal layer, two or more second touch metals TM2 forming a first touch electrode TE1 serving as the touch sensor can be electrically connected to each other through one or more first touch metals TM1, which are bridge metals. For example, two or more second touch metals TM2 spaced apart from each other can be electrically connected to each other by one or more first touch metals TM1 to form one first touch electrode TE1.

The plurality of first touch metals TM1 can be disposed on the touch buffer layer 351. The touch interlayer insulating layer 352 can be disposed on the plurality of first touch metals TM1. The plurality of second touch metals TM2 can be disposed on the touch interlayer insulating layer 352. Each of one or more of the plurality of second touch metals TM2 can be connected to a corresponding first touch metal TM1 through a hole of the touch interlayer insulating layer 352.

The plurality of first touch metals TM1 and the plurality of second touch metals TM2 can be disposed not to overlap with the light emitting element ED. The plurality of first touch metals TM1 and the plurality of second touch metals TM2 can overlap with the bank 340.

The touch protection layer 353 can be disposed on the touch metal layer. The touch protection layer 353 can be disposed such that the touch protection layer 353 covers the plurality of touch metals (TM1 and TM2) disposed in the touch metal layer.

A touch line TL disposed over the substrate 111 can electrically connect a touch electrode TE and a touch pad TP. The touch line TL can be configured with at least one of a first touch metal TM1 and a second touch metal TM2.

In one or more aspects, the touch line TL can be configured with a first touch metal TM1, a second touch metal TM2, or both a first touch metal TM1 and a second touch metal TM2.

In an example where the display panel 110 has a structure where the touch sensor is integrated in the display panel 110, the touch line TL can extend along an inclined or curved surface SLP ENCAP of an outer edge of the encapsulation layer 200, further extend beyond an upper portion of at least one dam DAM, and reach the touch pad TP disposed in the non-display area NDA.

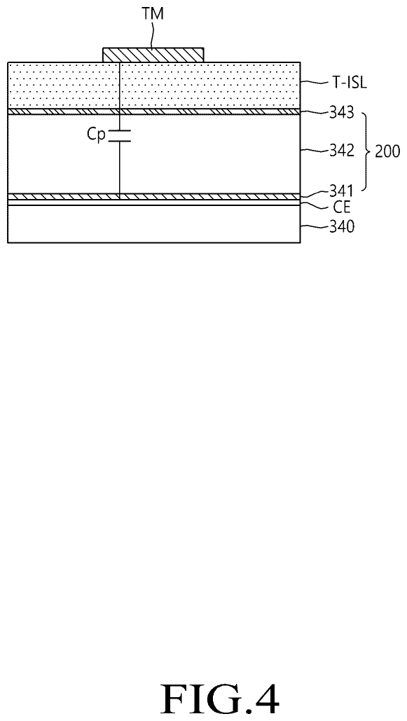

FIG. 4 is an example cross-sectional view of an area of the display device 100 in which a touch metal is disposed according to aspects of the present disclosure. FIG. 4 shows a partial configuration in the structure illustrated in FIG. 3.

Referring to FIG. 4, the display device 100 can include the bank 340 disposed on the substrate 111, the cathode electrode CE disposed on the bank, the encapsulation layer 200 disposed on the cathode electrode CE, a touch insulation layer T-ISL disposed on the encapsulation layer 200, and a touch metal TM disposed on the touch insulation layer T-ISL. For example, the touch insulation layer T-ISL can include at least one of the touch buffer layer 351 and the touch interlayer insulation layer 352 of FIG. 3. The touch metal TM can include at least one of the first touch metal TM1 and the second touch metal TM2 of FIG. 3.

The cathode electrode CE can be a metal located closest to the touch metal TM among metals or metal layers disposed under the touch metal TM. An insulating material layer including the encapsulation layer 200 and the touch insulation layer T-ISL can be disposed between the touch metal TM and the cathode electrode CE. The insulating material layer disposed between the touch metal TM and the cathode electrode CE can also be referred to as a dielectric layer.

An amount of the parasitic capacitance undesirably formed between the touch metal TM and the cathode electrode CE can be determined depending on a distance between the touch metal TM and the cathode electrode CE and a permittivity of the insulating material layer (i.e., the dielectric layer) between the touch metal TM and the cathode electrode CE. Such parasitic capacitance can act as a resistance-capacitance (RC) load during a touch sensing operation, this leading touch sensitivity or touch detection capability to be reduced.

To address this issue, in one or more aspects, the display device 100 can be provided that includes a structure capable of reducing or preventing the formation of undesirable parasitic capacitance through the touch metal TM. Hereinafter, the display device 100 having the structure capable of reducing or preventing the formation of undesirable parasitic capacitance will be described in detail.

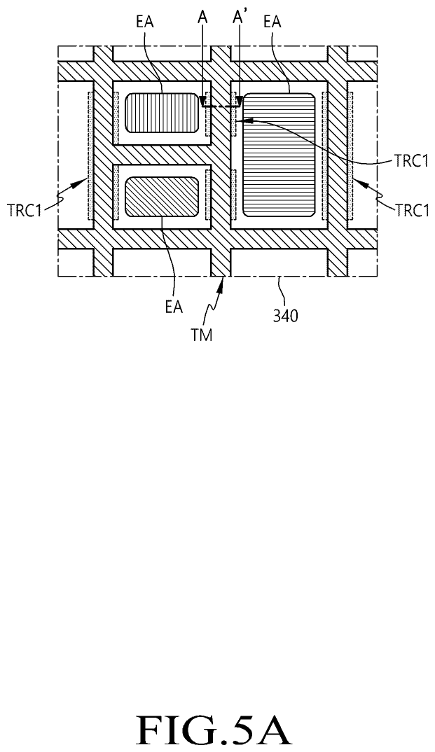

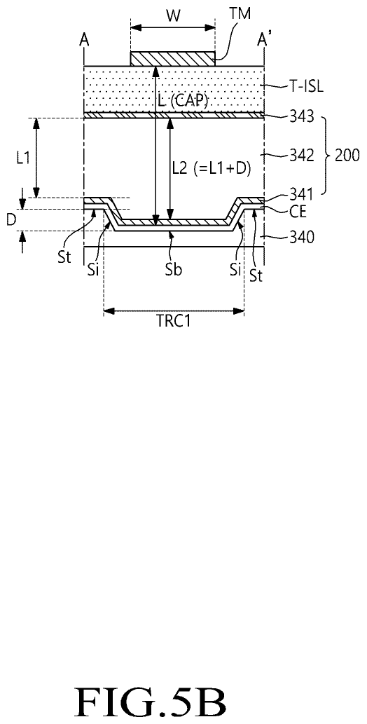

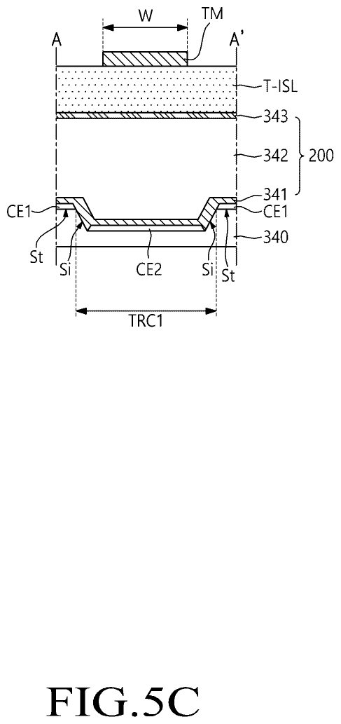

FIG. 5A is an example plan view of a portion of the display device 100 according to aspects of the present disclosure, and FIGS. 5B and 5C are example cross-sectional views of the display device 100 taken along line A-A′ of FIG. 5A.

Referring to FIGS. 5A and 5B, in one or more aspects, the display device can include a bank 340 disposed over a substrate 111 and including a first trench TRC1, a cathode electrode CE disposed on the bank 340, an encapsulation layer 200 disposed on the cathode electrode CE, a touch insulation layer T-ISL disposed on the encapsulation layer 200, and a touch metal TM disposed on the touch insulation layer T-ISL and vertically overlapping with the first trench TRC1.

Referring to FIG. 5B, the encapsulation layer 200 can be configured with a single layer or multiple layers. In an example where the encapsulation layer 200 is configured with multiple layers, the encapsulation layer 200 can include a first encapsulation layer 341, a second encapsulation layer 342 on the first encapsulation layer 341, and a third encapsulation layer 343 on the second encapsulation layer 342. For example, the first encapsulation layer 341 and the third encapsulation layer 343 can be inorganic layers, and the second encapsulation layer 342 can be an organic layer. For example, the second encapsulation layer 342 can be made of an organic material, and for example, epoxy polymer, acrylic polymer, or the like can be used. For example, the first encapsulation layer 341 and the third encapsulation layer 343 can be made of an inorganic material, for example, an inorganic material such as silicon nitride (SiNx), silicon oxide (SiOx), or aluminum oxide (AlOx). However, the present disclosure is not limited thereto.

The bank 340 can include an upper surface St, a lower surface Sb of the first trench TRC1, and at least one side surface Si of the first trench TRC1.

The first encapsulation layer 341 can be disposed such that the first encapsulation layer 341 extends from the upper surface St of the bank 340 to the lower surface Sb of the first trench TRC1 formed in the bank 340.

Referring to FIGS. 5A and 5B, the first trench TRC1 can be a groove formed in the bank 340 and may not overlap with a light emitting element ED. For example, the first trench TRC1 can be disposed in at least a portion of the bank 340 not overlapping with the light emitting element ED in the plan view.

For example, the first trench TRC1 can be adjacent to the light emitting area EA and can vertically overlap with the touch metal TM.

A width of the first trench TRC1 can be greater than or equal to a width W of the touch metal TM.

Referring to FIG. 5B, a thickness L2 of the second encapsulation layer 342 located over the first trench TRC1 can be greater than a thickness L1 of the second encapsulation layer 342 located over the upper surface St of the bank 340 where the first trench TRC1 is not disposed.

For example, the thickness L2 of the second encapsulation layer 342 located over the first trench TRC1 can be greater by a depth D of the first trench TRC1 than the thickness L1 of the second encapsulation layer 342 located over the upper surface St of the bank 340 where the first trench TRC1 is not disposed.

This configuration can lead a distance L between the cathode electrode CE and the touch metal TM disposed in the first trench TRC1 to increase.

As discussed above, as the display device 100 is configured with a structure in which the bank 340 has the first trench TRC1 with a predetermined depth D in a portion overlapping the touch metal TM, the distance L between the touch metal TM and the cathode electrode CE can become longer. Thereby, the display device 100 can provide an advantage of reducing an amount of parasitic capacitance.

As the first trench TRC1 is disposed in a portion of the bank 340 aligned vertically with the touch metal TM, the parasitic capacitance formed in the touch metal TM can be reduced, thereby improving touch sensitivity or touch detection capability.

FIG. 5C is another example cross-sectional view taken along the line A-A′ of FIG. 5A.

Referring to FIG. 5C, in one or more aspects, a cathode electrode CE can have a disconnected structure inside of a first trench TRC1 formed in a bank 340.

In one or more aspects, the display device 100 can include a substrate 111, a bank 340 disposed on the substrate 111 and including the first trench TRC1, the cathode electrode CE disposed on the bank 340, an encapsulation layer 200 disposed on the cathode electrode CE, a touch insulation layer T-ISL disposed on the encapsulation layer 200, and a touch metal TM disposed on the touch insulation layer T-ISL and vertically overlapping with the first trench TRC1.

The cathode electrode CE can include a first cathode electrode portion CE1 disposed on an upper surface St of the bank 340 around the first trench TRC1, and a second cathode electrode portion CE2 disposed on a lower surface Sb of the first trench TRC1.

In one or more aspects, the first cathode electrode portion CE1 and the second cathode electrode portion CE2 can be spaced apart from each other at at least on side surface Si of the first trench TRC1. In other words, the cathode electrode CE can be disconnected at the at least side surface Si of the first trench TRC1.

In one or more aspects, the first cathode electrode portion CE1 and the second cathode electrode portion CE2 can be electrically disconnected from each other. The first cathode electrode portion CE1 can be supplied with a base voltage VSS corresponding to a cathode voltage, but the second cathode electrode portion CE2 can be in an electrically floating state in which an electrical signal (e.g., a voltage) such as the base voltage VSS and the like is not applied. The second cathode electrode portion CE2 disposed on the lower surface Sb of the first trench TRC1 can also be referred to as a floating metal or floating pattern.

Accordingly, an electrode or pattern overlapping with the touch metal TM in the vertical direction and allowing an electrical signal (e.g., a voltage) to be applied may not be disposed. Thereby, undesirable parasitic capacitance may not be formed in the touch metal TM.

For example, the cathode electrode CE may not be disposed on the at least side surface Si of the first trench TRC1, and a first encapsulation layer 341 can be disposed on the at least side surface Si of the first trench TRC1.

As described above, the first cathode electrode portion CE1 disposed outside of the first trench TRC1 and the second cathode electrode portion CE2 disposed inside of the first trench TRC1 can be electrically disconnected from each other. In this configuration, the base voltage VSS, which is a common voltage, can be applied to the first cathode electrode portion CE1, but the base voltage VSS may not be applied to the second cathode electrode portion CE2.

For example, the second cathode electrode portion CE2 disposed on the lower surface Sb of the first trenches TRC1 can be isolated in an island shape in the first trench TRC1. Thereby, the second cathode electrode portion CE2 may not supplied with the base voltage VSS, which is the common voltage, and can be an electrically floating pattern to which an electrical signal (e.g., a voltage) is not applied.

As the floating pattern (i.e., the second cathode electrode portion CE2) is disposed in an area vertically overlapping with the touch metal TM, the display device 100 can provide an advantage of preventing undesirable parasitic capacitance from being formed in the touch metal TM.

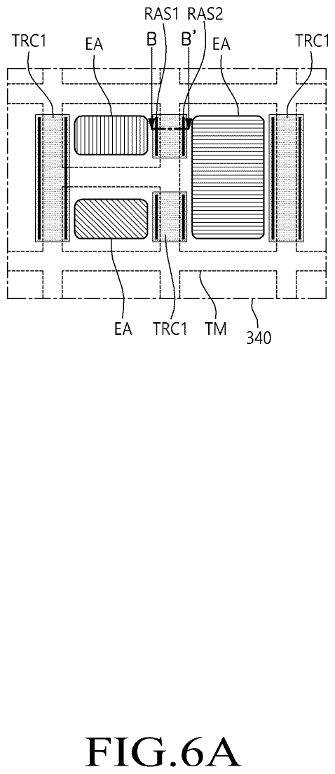

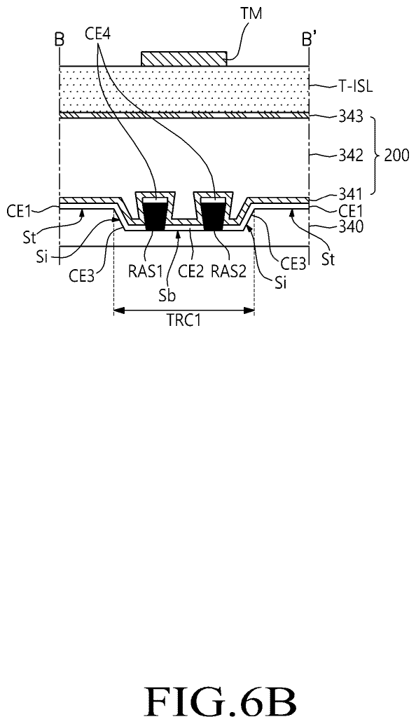

FIG. 6A is an example plan view of a portion of the display device 100 according to aspects of the present disclosure, and FIG. 6B is an example cross-sectional view of the display device 100 taken along line B-B′ of FIG. 6A.

Referring to FIGS. 6A and 6B, in one or more aspects, the display device can include a bank 340 disposed over a substrate 111 and including a first trench TRC1, a cathode electrode CE disposed on the bank 340, an encapsulation layer 200 disposed on the cathode electrode CE, a touch insulation layer T-ISL disposed on the encapsulation layer 200, and a touch metal TM disposed on the touch insulation layer T-ISL and vertically overlapping with the first trench TRC1.

In one or more aspects, the display device 100 can further include at least one inverse taper structure (RAS1 and/or RAS2) disposed inside of the first trench TRC1 and tapered toward the substrate 111.

FIG. 6B illustrates that two inverse taper structures (RAS1 and RAS2) are disposed on a lower surface Sb of the first trench TRC1, but the number of inverse taper structures disposed inside of the first trench TRC1 can be 1, or 3 or more. For example, one inverse taper structure can be disposed inside of the first trench TRC1, alternatively, two or more inverse taper structures spaced from each other can be disposed inside of the first trench TRC1. The number of inverse taper structures disposed on the lower surface Sb of the first trench TRC1 is not limited thereto.

Referring to FIG. 6B, each of a first inverse taper structure RAS1 and a second inverse taper structure RAS2 can have a protruding structure in which a width of an upper surface is greater than a width of a lower surface, and a side surface has an inverse taper shape. Each of the first inverse taper structure RAS1 and the second inverse taper structure RAS2 can include the same material as the bank 340, but aspects of the present disclosure are not limited thereto. For example, each of the first inverse taper structure RAS1 and the second inverse taper structure RAS2 can include an insulating material different from the material of the bank 340.

Referring to FIGS. 6A and 6B, the first inverse taper structure RAS1 and the second inverse taper structure RAS2 can be spaced apart by a predetermined interval from each other in the first trench TRC1.

Referring to FIG. 6B, in one or more aspects, the cathode electrode CE can include a first cathode electrode portion CE1 disposed on an upper surface St of the bank 340 around the first trench TRC1, a second cathode electrode portion CE2 disposed on the lower surface Sb of the first trench TRC1, a third cathode electrode portion CE3 disposed on at least one side surface Si of the first trench TRC1, and a fourth cathode electrode portion CE4 disposed on the at least one inverse taper structure (RAS1 and/or RAS2).

The first cathode electrode portion CE1 and the third cathode electrode portion CE3 can be connected to each other and can extend from the upper surface St of the bank 340 to the at least one side surface Si of the first trench TRC1.

The second cathode electrode portion CE2 may not be electrically connected to the first cathode electrode portion CE1, the third cathode electrode portion CE3, and the fourth cathode electrode portion CE4. The fourth cathode electrode portion CE4 may not be electrically connected to the first cathode electrode portion CE1, the second cathode electrode portion CE2, and the third cathode electrode portion CE3.

As the side surfaces of the first and second inverse taper structures (RAS1 and RAS2) are inversely tapered (i.e., tapered toward the substrate 111), the third cathode electrode portion CE3 extending from the first cathode electrode portion CE1, the fourth cathode electrode portion CE4, and the second cathode electrode portion CE2 can be physically separated from each other and electrically disconnected from each other.

Referring to FIGS. 6A and 6B, the second cathode electrode portion CE2 disposed between the first inverse taper structure RAS1 and the second inverse taper structure RAS2 can be isolated in an island shape in the first trench TRC1 and be in a floating state in which a base voltage VSS, which is a common voltage, is not supplied. For example, the second cathode electrode portion CE2 disposed between the first inverse taper structure RAS1 and the second inverse taper structure RAS2 can be referred to as a floating pattern remaining in an electrically floating state to which no electrical signal is applied.

The fourth cathode electrode portion CE4 disposed on each of the first inverse taper structure RAS1 and the second inverse taper structure RAS2 can be isolated in an island shape in the first trench TRC1 and be in a floating state in which the base voltage VSS, which is the common voltage, is not supplied. For example, the fourth cathode electrode portion CE4 can be referred to as a floating pattern remaining in an electrically floating state to which no electrical signal is applied.

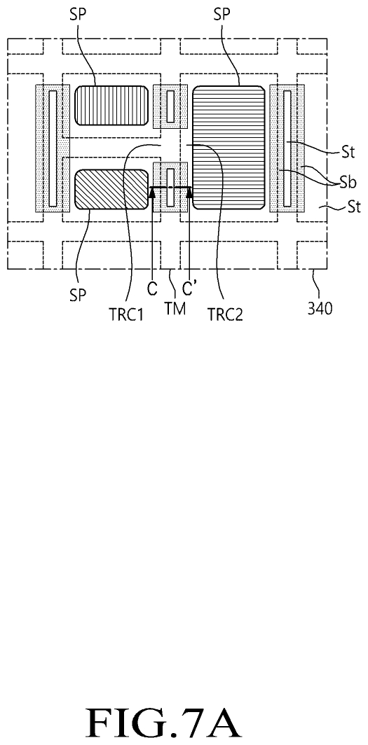

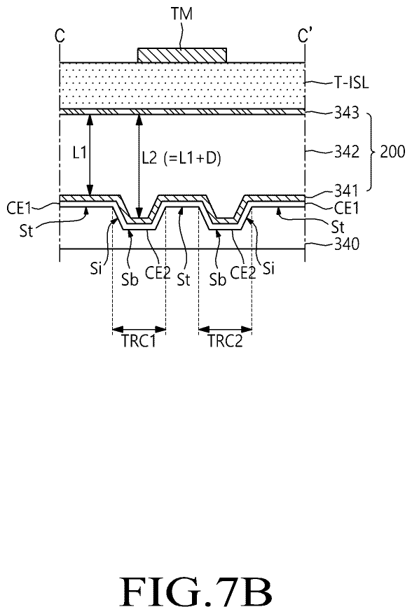

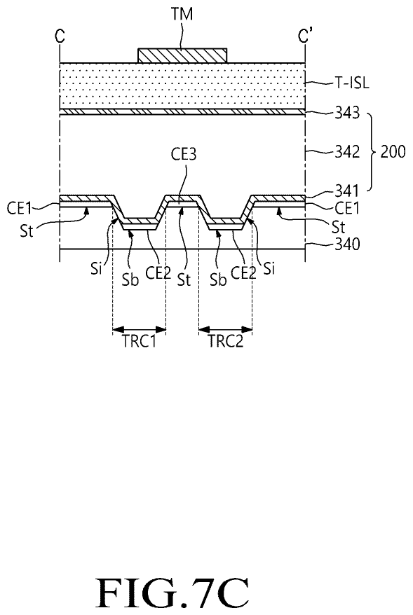

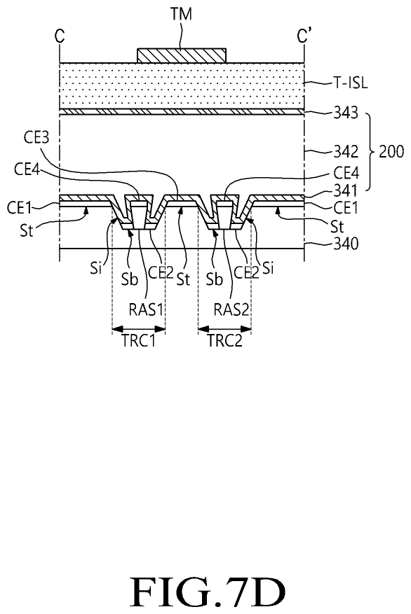

FIG. 7A is an example plan view of a portion of the display device 100 according to aspects of the present disclosure, and FIGS. 7B to 7D are example cross-sectional views of the display device 100 taken along line C-C′ of FIG. 7A.

Referring to FIGS. 7A and 7B, in one or more aspects, the display device can include a bank 340 disposed over a substrate 111 and including a plurality of trenches (TRC1 and TRC2), a cathode electrode CE disposed on the bank 340, an encapsulation layer 200 disposed on the cathode electrode CE, a touch insulation layer T-ISL disposed on the encapsulation layer 200, and a touch metal TM disposed on the touch insulation layer T-ISL and vertically overlapping with the first trench TRC1.

In one or more aspects, the plurality of trenches (TRC1 and TRC2) can be connected to each other to form a single ring-shaped trench. In one or more aspects, the plurality of trenches (TRC1 and TRC2) can be spaced apart by a predetermined interval from each other in a direction (i.e., in the horizontal direction in the plan view) intersecting a lengthwise direction (i.e., the vertical direction in the plan view) of the touch metal TM.

In one or more aspects, the bank 340 included in the display device 100 can include the plurality of trenches (TRC1 and TRC2) located within a line width of the touch metal TM. In this implementation, the plurality of trenches (TRC1 and TRC2) can at least partially, or wholly, overlap with the touch metal TM, and can be disposed adjacent to each other in the direction intersecting the lengthwise direction of the touch metal TM.

FIG. 7B illustrates that within the line width of the touch metal TM, the bank 340 has the first trench TRC1 and the second trench TRC2, but this is only one example for convenience of explanation. For example, within the line width of the touch metal TM, one or three or more trenches can be formed in the direction intersecting the lengthwise direction of the touch metal TM. For example, within the line width of the touch metal TM, one trench can be disclosed in the direction intersecting the lengthwise direction of the touch metal TM, for example, within the line width of the touch metal TM, three or more trenches spaced from each other can be disclosed in the direction intersecting the lengthwise direction of the touch metal TM, but not limited thereto.

Referring to FIG. 7B, a width between an outermost edge of the first trench TRC1 and an outermost edge of the second trench TRC2 can be greater than or equal to that of the touch metal TM. For example, the first trench TRC1 and the second trench TRC2 can overlap with the touch metal TM. When the line width of the touch metal TM is the sum of a first line width and a second line width, the first trench TRC1 can overlap with at least a portion of a first portion having the first line width among portions of the touch metal TM, and the second trench TRC2 can overlap with at least a portion of a second portion having the second line width among the portions of the touch metal TM.

A thickness L2 of a second encapsulation layer 342 disposed over the first and second trenches (TRC1 and TRC2) can be greater by a depth D of the first and second trenches (TRC1 and TRC2) than a thickness L1 of the second encapsulation layer 342 disposed over a portion of the bank 340 where the first and second trenches (TRC1 and TRC2) are not disposed. For example, a thickness L2 of a second encapsulation layer 342 disposed over the first trench (TRC1) can be greater by a depth D of the first trench (TRC1) than a thickness L1 of the second encapsulation layer 342 disposed over a portion of the bank 340 where the first and second trenches (TRC1 and TRC2) are not disposed, for example, a thickness L2 of a second encapsulation layer 342 disposed over the second trench (TRC2) can be greater by a depth D of the second trench (TRC2) than a thickness L1 of the second encapsulation layer 342 disposed over a portion of the bank 340 where the first and second trenches (TRC1 and TRC2) are not disposed. but not limited thereto. Meanwhile, depths of the first and second trenches (TRC1 and TRC2) can be same, but not limited thereto. Alternatively, a depth of the first trench (TRC1) is D1, and a depth of the second trench (TRC2) is D2, and depths of the first and second trenches (TRC1 and TRC2) can be different.

A distance between a portion of the cathode electrode CE disposed at the first and second trenches (TRC1 and TRC2) and the touch metal TM can be greater than that between a portion of the cathode electrode CE disposed on the upper surface St of the bank 340 where the first and second trenches (TRC1 and TRC2) are not disposed and the touch metal TM.

For example, the distance between the portion of the cathode electrode CE disposed at the first and second trenches (TRC1 and TRC2) and the touch metal TM can be greater by the depth D of the first and second trenches (TRC1 and TRC2) than that between the portion of the cathode electrode CE disposed on the upper surface St of the bank 340 where the first and second trenches (TRC1 and TRC2) are not disposed and the touch metal TM. For example, the distance between the portion of the cathode electrode CE disposed at the first trench (TRC1) and the touch metal TM can be greater by the depth D of the first trench (TRC1) than that between the portion of the cathode electrode CE disposed on the upper surface St of the bank 340 where the first and second trenches (TRC1 and TRC2) are not disposed and the touch metal TM. For example, the distance between the portion of the cathode electrode CE disposed at the second trench (TRC2) and the touch metal TM can be greater by the depth D of the second trench (TRC1) than that between the portion of the cathode electrode CE disposed on the upper surface St of the bank 340 where the first and second trenches (TRC1 and TRC2) are not disposed and the touch metal TM.

In one or more aspects, the depth D of the first trench TRC1 and the depth D of the second trench (TRC2) can be different from each other. In one or more aspects, the depth D of the first trench TRC1 and the depth D of the second trench TRC2 can be the same.

As discussed above, as the plurality of trenches (TRC1 and TRC2) formed in at least a portion of the bank 340 overlap with the touch metal TM, a distance between the touch metal TM and the cathode electrode CE can become longer. Thereby, the display device 100 can provide an advantage of reducing an amount of parasitic capacitance.

FIG. 7C is another cross-sectional view taken along the line C-C′ of FIG. 7A.

Referring to FIG. 7C, a cathode electrode disposed on a bank 340 including a plurality of trenches (TRC1 and TRC2) can have a disconnected structure.

In one or more aspects, a cathode electrode CE2 disposed inside of each of a first trench TRC1 and a second trench TRC2 can be disconnected from a cathode electrode CE1 disposed outside of each of the first trench TRC1 and the second trench TRC2, and be in an electrically floating state. Thereby, the display device 100 employing this configuration can provide an advantage of preventing parasitic capacitance formed in a touch metal TM.

In one or more aspects, the display device 100 can include a substrate 111, the bank 340 disposed on the substrate 111 and including the plurality of trenches (TRC1 and TRC2), the cathode electrode CE disposed on the bank 340, an encapsulation layer 200 disposed on the cathode electrode CE, a touch insulation layer T-ISL disposed on the encapsulation layer 200, and the touch metal TM disposed on the touch insulation layer T-ISL.

At least a portion of each of the first trench TRC1 and the second trench TRC2 can vertically overlap with the touch metal TM.

A portion of the bank 340 can remain in a tapered shape between the first trench TRC1 and the second trench TRC2.

The cathode electrode CE can include a first cathode electrode portion CE1 disposed on an upper surface St of the bank 340 around the first trench TRC1 and the second trench TRC2, a second cathode electrode portion CE2 disposed on a lower surface Sb of each of the first trench TRC1 and the second TRC2, and a third cathode electrode portion CE3 disposed on the upper surface St of the bank 340 and disposed between the first trench TRC1 and the second TRC2.

The first cathode electrode portion CE1 and the second cathode electrode portion CE2 can be spaced apart from each other at respective side surface Si of each of the first and second trenches (TRC1 and TRC2). The second cathode electrode portion CE2 and the third cathode electrode portion CE3 can be spaced apart from each other at respective another side surface Si of each of the first and second trenches (TRC1 and TRC2).

In this configuration, a base voltage VSS, which is a common voltage, can be applied to the first cathode electrode portion CE1. However, an electrical signal (e.g., a voltage) such as the base voltage VSS, which is the common voltage, and the like may not be applied to the second cathode electrode portion CE2 and the third cathode electrode portion CE3. For example, the second cathode electrode portion CE2 and the third cathode electrode portion CE3 can be in a floating state in which an electrical signal is not applied.

The cathode electrode CE may not be disposed on the at least one side surface Si of the first trench TRC1 and the second trench TRC2, and a first encapsulation layer 341 can be disposed such that the first encapsulation layer 341 contacts the at least one side surface Si of the bank 340.

As described above, the first cathode electrode portion CE1 disposed on the upper surface St of the bank 340 outside of the first trench TRC1 and the second trench TRC2, the second cathode electrode portion CE2 disposed on the lower surface Sb of each of the first trench TRC1 and the second trench TRC2, and the third cathode electrode portion CE3 disposed on the upper surface St of the bank 340 between the first trench TRC1 and the second trench TRC2 can be electrically disconnected from each other, and the base voltage VSS, which is the common voltage, may not be supplied to the second cathode electrode portion CE2 and the third cathode electrode portion CE3. For example, each of the second cathode electrode portion CE2 and the third cathode electrode portion CE3 can be referred to as a floating metal or floating pattern in an electrically floating state.

Referring to FIG. 7A, the second cathode electrode portions CE2 disposed on the respective lower surface Sb of the first trench TRC1 and the second trench TRC2 and the third cathode electrode portion CE3 disposed on the upper surface St of the bank 340 between the first trench TRC1 and the second trench TRC2 can be arranged in an island shape and electrically isolated.

Referring to FIG. 7C, the first cathode electrode portion CE1 to which the base voltage VSS, which is the common voltage is applied may not vertically overlap with the touch metal TM. The second cathode electrode portion CE2 and the third cathode electrode portion CE3 can vertically overlap with the touch metal TM, but be floating metals to which the base voltage VSS, which is the common voltage, is not applied. As a result, the display device 100 employing the configuration of FIG. 7C can provide an advantage of fundamentally preventing the formation of parasitic capacitance in the touch metal TM due to the cathode electrode CE.

FIG. 7D is another cross-sectional view taken along the line C-C′ of FIG. 7A.

Referring to FIG. 7D, in one or more aspects, the display device 100 can include inverse taper structures formed in each of a plurality of trenches (TRC1 and TRC2) to prevent the formation of parasitic capacitance between a touch metal TM and a cathode electrode CE.

In one or more aspects, the display device 100 can include a bank 340 disposed over a substrate 111 and including the plurality of trenches (TRC1 and TRC2), the cathode electrode CE disposed on the bank 340, an encapsulation layer 200 disposed on the cathode electrode CE, a touch insulation layer T-ISL disposed on the encapsulation layer 200, and the touch metal TM disposed on the touch insulation layer T-ISL and vertically overlapping with the plurality of trenches (TRC1 and TRC2).

The display device 100 can further include at least one inverse taper structure (RAS1 and/or RAS2) disposed inside of each of the plurality of trenches (TRC1 and TRC2).

In one or more aspects, a first inverse taper structure RAS1 can be disposed on a lower surface Sb of a first trench TRC1, and a second inverse taper structure RAS2 can be disposed on a lower surface Sb of a second trench TRC2. However, aspects of the present disclosure are not limited thereto. For example, the inverse tapered structure can be disposed only on the lower surface Sb of one of the first trench TRC1 and the second trench TRC2, or the number of first inverse taper structures RAS1 disposed on the lower surface Sb of the first trench TRC1 and the number of second inverse taper structures RAS2 disposed on the lower surface Sb of the second trench TRC2 can be different from each other. For example, the number of first inverse taper structures RAS1 and the number of second inverse taper structures RAS2 can be different by 1 or more from each other. However, aspects of the present disclosure are not limited to these implementations. The number of inverse taper structures and/or locations of inverse taper structures can be variously designed.

Each of the first and second inverse taper structures (RAS1 and RAS2) can be a structure having a shape in which a width of an upper surface is greater than that of the lower surface, and at least one side surface is tapered inversely (i.e., tapered toward the substrate 111). The material or properties of each of the first and second inverse taper structures (RAS1 and RAS2) can be the same as the material or properties of the bank 340. In one or more aspects, the material or properties of each of the first and second inverse taper structures (RAS1 and RAS2) can be different from the material or properties of the bank 340, and in this implementation, the first and second inverse taper structures (RAS1 and RAS2) can include various materials that are different from the material of the bank 340 but have an insulating property.

The first and second inverse taper structures (RAS1 and RAS2) can be disposed to be spaced apart from each other by a predetermined interval.

In one or more aspects, the cathode electrode CE can include a first cathode electrode portion CE1 disposed on the upper surface St of the bank 340 around the first and second trenches (TRC1 and TRC2), a second cathode electrode portion CE2 disposed on the lower surface Sb of each of the first and second trenches (TRC1 and TRC2), a third cathode electrode portion CE3 disposed on the upper surface St of the bank 340 between the first trench TRC1 and the second trench TRC2, and a fourth cathode electrode portion CE4 disposed on each of the first and second inverse taper structures (RAS1 and RAS2).

At least a portion of each of the second cathode electrode portion CE2, the third cathode electrode portion CE3, and the fourth cathode electrode portion CE4 can overlap with the touch metal TM.

The second cathode electrode portion CE2, the third cathode electrode portion CE3, and the fourth cathode electrode portion CE4 can be spaced from each other, and can also be spaced from the first cathode electrode portion CE1.

The second cathode electrode portion CE2, the third cathode electrode portion CE3, and the fourth cathode electrode portion CE4 can be electrically disconnected from the first cathode electrode portion CE1.

A base voltage VSS, which is a common voltage, can be applied to the first cathode electrode portion CE1. An electrical signal (e.g., a voltage) such as the base voltage VSS, which is the common voltage, and the like may not be applied to the second cathode electrode portion CE2, the third cathode electrode portion CE3, and the fourth cathode electrode portion CE4. For example, each of the second cathode electrode portion CE2, the third cathode electrode portion CE3, and the fourth cathode electrode portion CE4 can be in an electrically floating state and can be a floating metal or floating pattern.

The first cathode electrode portion CE1 to which the base voltage VSS, which is the common voltage is applied may not vertically overlap with the touch metal TM. The second cathode electrode portion CE2, the third cathode electrode portion CE3, and the fourth cathode electrode portion CE4 can vertically overlap with the touch metal TM, but can be floating metals to which the base voltage VSS, which is the common voltage, is not applied. As a result, the display device 100 employing the configuration of FIG. 7D can provide an advantage of fundamentally preventing the formation of parasitic capacitance in the touch metal TM due to the cathode electrode CE.

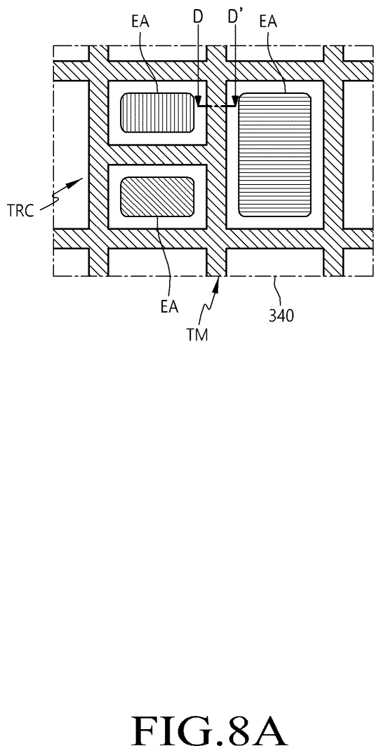

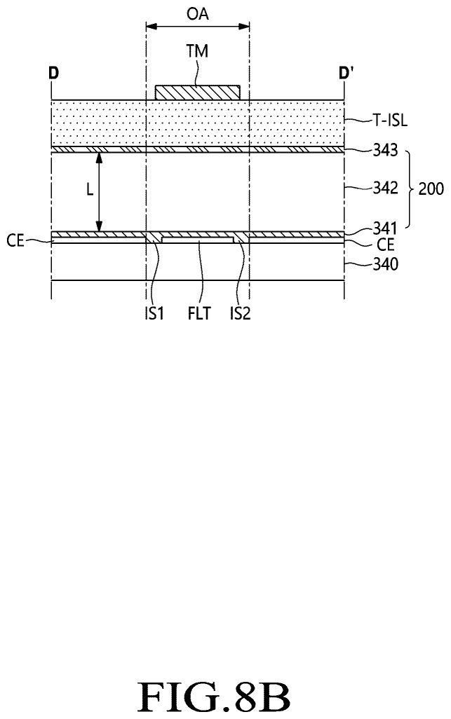

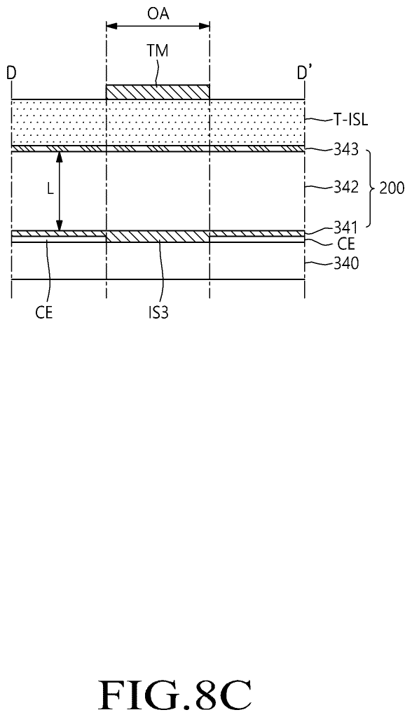

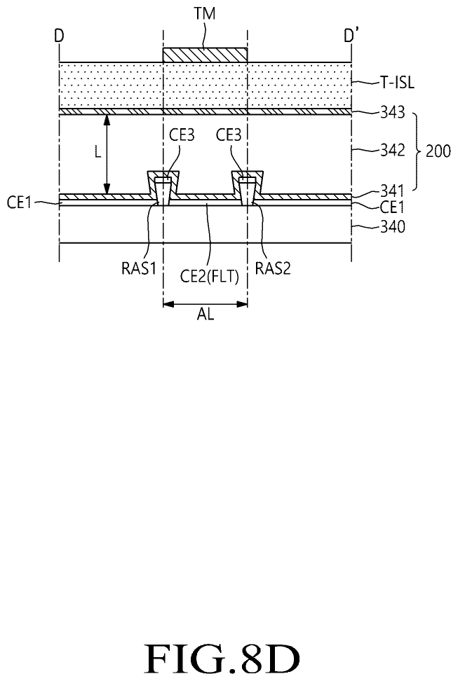

FIG. 8A is an example plan view of a portion of the display device 100 according to aspects of the present disclosure, and FIGS. 8B to 8D are example cross-sectional views of the display device 100 taken along line D-D′ of FIG. 8A.

Referring to FIGS. 8A and 8B, in one or more aspects, a cathode electrode CE included in the display device 100 can include at least one opening OA overlapping a touch metal TM, to reduce parasitic capacitance formed between the touch metal TM and the cathode electrode CE

In one or more aspects, the display device 100 can include a bank 340 disposed over a substrate 111, the cathode electrode CE disposed on the bank 340, an encapsulation layer 200 disposed on the cathode electrode CE, a touch insulation layer T-ISL disposed on the encapsulation layer 200, and the touch metal TM disposed on the touch insulation layer T-ISL.

The cathode electrode CE can have the at least one opening OA in at least a portion of an area vertically overlapping with the touch metal TM.

Referring to FIG. 8B, a width or distance of the opening OA can be greater than or equal to a width or distance of the touch metal TM.

In one or more aspects, the display device 100 can further include a floating metal FLT disposed on the bank 340 in the opening OA of the cathode electrode CE. The floating metal FLT can include the same material as the cathode electrode CE. Not only the base voltage VSS applied to the cathode electrode CE, but also any electrical signal may not be applied to the floating metal FLT.

In one or more aspects, the display device 100 can further include at least one insulating layer (IS1 and/or IS2) disposed between the cathode electrode CE and the floating metal FLT. For example, a first insulating layer IS1 and a second insulating layer IS2 can be disposed on both sides of the floating metal FLT.

The cathode electrode CE and the floating metal FLT can be disposed to be spaced apart from each other on the bank 340.

The encapsulation layer 200 can include a first encapsulation layer 341, a second encapsulation layer 342 on the first encapsulation layer 341, and a third encapsulation layer 343 on the second encapsulation layer 342.

In one or more aspects, the first encapsulation layer 341 can be disposed between at least one side surface of the cathode electrode CE around the floating metal FLT and at least one side surface of the floating metal FLT, thereby electrically disconnecting the cathode electrode CE and the floating metal FLT. The first encapsulation layer 341 can be the at least one insulating layer (IS1 and/or IS2) discussed above.

FIG. 8C is another cross-sectional view taken along the line D-D′ of FIG. 8A.

Referring to FIG. 8C, in one or more aspects, in the display device 100 can have a structure where a floating metal FLT may not be disposed in an opening OA of a cathode electrode CE, and an insulating layer IS3 can fill the opening OA of the cathode electrode CE.

By employing this structure, the display device 100 may not include metal in an area overlapping the touch metal TM.

FIG. 8D is another cross-sectional view taken along the line D-D′ of FIG. 8A.

Referring to FIG. 8D, in one or more aspects, the display device 100 can include a bank 340 disposed over a substrate 111, a cathode electrode CE disposed on the bank 340, an encapsulation layer 200 disposed on the cathode electrode CE, a touch insulation layer T-ISL disposed on the encapsulation layer 200, and a touch metal TM disposed on the touch insulation layer T-ISL.

In one or more aspects, the display device 100 can further include at least one inverse taper structure (RAS1 and RAS2) on at least a portion of the bank 340 overlapping vertically with the touch metal TM.

For example, first and second inverse taper structures (RAS1 and RAS2) can be disposed to overlap vertically with both edges of the touch metal TM, respectively.

The first and second inverse taper structures (RAS1 and RAS2) can be spaced apart from each other by a predetermined interval on the bank 340, and respective outer edges of the first and second inverse taper structures (RAS1 and RAS2) can be disposed to protrude further outwardly than outer edges of the touch metal TM.

Each of the first and second inverse taper structures (RAS1 and RAS2) can be a structure having a shape in which a width of an upper surface is greater than that of a lower surface, and at least one side surface is tapered inversely (i.e., tapered toward the substrate 111). The material or properties of each of the first and second inverse taper structures (RAS1 and RAS2) can be the same as the material or properties of the bank 340. In one or more aspects, the material or properties of each of the first and second inverse taper structures (RAS1 and RAS2) can be different from the material or properties of the bank 340, and in this implementation, the first and second inverse taper structures (RAS1 and RAS2) can include various materials that are different from the material of the bank 340 but have an insulating property.

In one or more aspects, the cathode electrode CE can include a first cathode electrode portion CE1 disposed on a portion of the bank 340 different from an area in which the first and second inverse taper structures (RAS1 and RAS2) are disposed, a second cathode electrode portion CE2 disposed in an alignment area AL overlapping with the touch metal TM, and a third cathode electrode portion CE3 disposed on the first and second inverse taper structures (RAS1 and RAS2).

The second cathode electrode portion CE2 and the third cathode electrode portion CE3 can be spaced apart from the first cathode electrode portion CE1.

The second cathode electrode portion CE2 and the third cathode electrode portion CE3 may not be electrically connected to the first cathode electrode portion CE1.

A base voltage VSS, which is a common voltage, can be applied to the first cathode electrode portion CE1. An electrical signal (e.g., a voltage) such as the base voltage VSS, which is the common voltage, and the like may not be applied to the second cathode electrode portion CE2 and the third cathode electrode portion CE3. For example, the second cathode electrode portion CE2 and the third cathode electrode portion CE3 can be in a floating state in which an electrical signal is not applied.

As the side surfaces of the first and second inverse taper structures (RAS1 and RAS2) are inversely tapered (i.e., tapered toward the substrate 111), the second cathode electrode portion CE2 and the third cathode electrode portion CE3 can be further spaced apart from the first cathode electrode portion CE1 and may not be electrically connected to the first cathode electrode portion CE1.

The example embodiments and aspects described herein of the present disclosure are briefly described as follows.

According to the example embodiments described herein, a display device can include a substrate, a bank disposed on the substrate, a cathode electrode disposed on the bank, an encapsulation layer disposed on the cathode electrode, a touch insulation layer disposed on the encapsulation layer, and a touch metal disposed on the touch insulation layer, and provides an advantage of preventing or reducing the formation of parasitic capacitance in the touch metal through a trench structure of the bank.

According to the example embodiments described herein, a display device can include a substrate, a bank disposed on the substrate and including a first trench, a cathode electrode disposed on the bank, an encapsulation layer disposed on the cathode electrode, a touch insulating layer disposed on the encapsulation layer, and at least one touch metal disposed on the touch insulating layer and vertically overlapping with the first trench.

In one or more aspects, a width of the first trench can be greater than or equal to a width of the touch metal.

In one or more aspects, a vertical distance between a portion of the cathode electrode disposed on a lower surface of the first trench and the touch metal can be greater by a depth of the first trench than a vertical distance between a portion of the cathode electrode disposed on an upper surface of the bank and the touch metal.

In one or more aspects, the cathode electrode can include a first cathode electrode portion disposed on an upper surface of the bank around the first trench, and a second cathode electrode portion disposed on a lower surface of the first trench, and the first cathode electrode portion and the second cathode electrode portion can be spaced apart from each other at at least one side surface of the first trench.

In one or more aspects, the encapsulation layer can include a first encapsulation layer, a second encapsulation layer on the first encapsulation layer, and a third encapsulation layer on the second encapsulation layer, and the first encapsulation layer can be disposed to extend from the upper surface of the bank to the lower surface of the first trench.

In one or more aspects, the display device can further include at least one inverse taper structure disposed in the first trench.

In one or more aspects, the cathode electrode can include a first cathode electrode portion disposed on an upper surface of the bank around the first trench, a second cathode electrode portion disposed on at least one side surface of the first trench, and a third cathode electrode portion disposed on the inverse taper structure, and the third cathode electrode portion can be in an electrically floating state.

In one or more aspects, the at least one inverse taper structure includes a first inverse taper structure and a second inverse taper structure spaced apart from each other in the first trench.

In one or more aspects, each of the first inverse taper structure and the second inverse taper structure has a protruding structure in which a width of an upper surface is greater than a width of a lower surface, and a side surface has an inverse taper shape.

In one or more aspects, the cathode electrode comprises a first cathode electrode portion disposed on an upper surface of the bank around the first trench, a second cathode electrode portion disposed on a lower surface of the first trench, a third cathode electrode portion disposed on at least one side surface of the first trench, and a fourth cathode electrode portion disposed on the first inverse taper structure and the second inverse taper structure.

In one or more aspects, the second cathode electrode portion disposed between the first inverse taper structure and the second inverse taper structure is a floating pattern.

In one or more aspects, the fourth cathode electrode portion disposed on each of the first inverse taper structure and the second inverse taper structure is floating pattern.

In one or more aspects, the bank can include a second trench and a third trench disposed at a predetermined interval.

In one or more aspects, the second trench and the third trench can overlap with the touch metal.

In one or more aspects, a width between an outermost edge of the second trench and an outermost edge of the third trench in a cross-sectional view can be greater than or equal to a width of the touch metal.

In one or more aspects, the cathode electrode can include a first cathode electrode portion disposed on an upper surface of the bank around the second trench and the third trench and a second cathode electrode portion disposed on a lower surface of each of the second and third trenches, and the first cathode electrode portion and the second cathode electrode portion can be spaced apart from each other at a respective side surface of each of the second trench and the third trench.

In one or more aspects, the encapsulation layer can include a first encapsulation layer, a second encapsulation layer on the first encapsulation layer, and a third encapsulation layer on the second encapsulation layer, and the first encapsulation layer can be disposed to extend from the upper surface of the bank to the lower surface of each of the second trench and the third trench.

In one or more aspects, the display device can further include at least one inverse taper structure disposed in at least one of the second trench and the third trench.

In one or more aspects, the cathode electrode can include a first cathode electrode portion disposed on the upper surface of the bank around the second and third trenches, a second cathode electrode portion disposed on the lower surface of each of the second trench and the third trench, a third cathode electrode portion disposed on the side surface of each of the second trench and the third trench, and a fourth cathode electrode portion disposed on the inverse taper structure, and the fourth cathode electrode portion can be in an electrically floating state.

According to the example embodiments described herein, a display device can include a substrate, a bank disposed on the substrate, a cathode electrode disposed on the bank, an encapsulation layer disposed on the cathode electrode, a touch insulation layer disposed on the encapsulation layer, and at least one touch metal disposed on the touch insulation layer. In one or more aspects, the cathode electrode can include an opening in at least a portion of an area vertically overlapping with the at least one touch metal.

In one or more aspects, the display device can further include a floating metal disposed in the opening and disposed on the bank, and the floating metal can include the same material as the cathode electrode.

In one or more aspects, the display device can further include an insulating layer, and the insulating layer can be disposed such that at least a portion of the insulating layer vertically overlaps with the touch metal at at least one side surface of the floating metal.

In one or more aspects, the cathode electrode and the floating metal can be disposed to be spaced apart from each other on the bank, the encapsulation layer can include a first encapsulation layer, a second encapsulation layer on the first encapsulation layer, and a third encapsulation layer on the second encapsulation layer. In this implementation, the first encapsulation layer can be disposed between at least one side surface of the cathode electrode and at least one side surface of the floating metal, and electrically disconnect the cathode electrode and the floating metal.

In one or more aspects, a width of the opening can be greater than or equal to a width of the touch metal.

In one or more aspects, the display device can further include an insulating layer disposed in the opening,

According to the example embodiments described herein, a display device can include a substrate, a bank disposed on the substrate, a cathode electrode disposed on the bank, an encapsulation layer disposed on the cathode electrode, a touch insulation layer disposed on the encapsulation layer, and at least one touch metal disposed on the touch insulation layer. In one or more aspects, the encapsulation layer can have a first thickness in a first area not overlapping with the at least one touch metal, and have a second thickness greater than the first thickness in a second area overlapping with the at least one touch metal.

In one or more aspects, the encapsulation layer can include a first encapsulation layer, a second encapsulation layer on the first encapsulation layer, and a third encapsulation layer on the second encapsulation layer. In one or more aspects, a thickness of the first encapsulation layer in the first area can be the same as that of the first encapsulation layer in the second area, a thickness of the third encapsulation layer in the first area can be the same as that of the third encapsulation layer in the second area, and a thickness of the second encapsulation layer in the first area can be greater than that of the second encapsulation layer in the second area.

According to the one or more aspects described herein, a display device can have a structure capable of reducing undesirable parasitic capacitance formed between a touch electrode and another electrode (e.g., a cathode electrode of a light emitting element) when a touch input is performed, and thereby, provides an advantage of improving the capability to detect the touch input.

According to the one or more aspects described herein, a display device can have a structure capable of preventing undesirable parasitic capacitance from being formed between a touch electrode and another electrode (e.g., a cathode electrode of a light emitting element) when a touch input is performed, and thereby, provides an advantage of improving the capability to detect the touch input.

According to the one or more aspects described herein, a display device can include a touch panel or a display panel where the touch panel is integrated that is configured to reduce or prevent the formation of undesirable parasitic capacitance between conductive elements disposed therein without separate operating or driving for reducing or preventing the parasitic capacitance, and thereby, provides an advantage of reducing or preventing the undesirable parasitic capacitance. According to the one or more aspects described herein, display devices can provide advantages of reducing power consumption for reducing or preventing parasitic capacitance, and thereby, enabling low-power and high-efficiency touch detection design.

The example embodiments of the present disclosure described above have been described for illustrative purposes; those skilled in the art will appreciate that various modifications, additions and substitutions are possible, without departing from the scope and spirit of the invention as disclosed in the accompanying claims. Although the example embodiments have been described for illustrative purposes, a person skilled in the art will appreciate that various modifications and applications are possible without departing from the essential characteristics of the present disclosure. For example, the specific components of the example embodiments can be variously modified.

What is claimed is:

1. A display device comprising:
a substrate;
a bank disposed on the substrate and comprising a first trench;
a cathode electrode disposed on the bank;
an encapsulation layer disposed on the cathode electrode;
a touch insulating layer disposed on the encapsulation layer; and
at least one touch metal disposed on the touch insulating layer and overlapping with the first trench.

2. The display device of claim 1, wherein a width of the first trench is greater than or equal to a width of the at least one touch metal.

3. The display device of claim 1, wherein a distance between a portion of the cathode electrode disposed on a lower surface of the first trench and the at least one touch metal is greater by a depth of the first trench than a distance between a portion of the cathode electrode disposed on an upper surface of the bank and the at least one touch metal.

4. The display device of claim 2, wherein the cathode electrode comprises a first cathode electrode portion disposed on an upper surface of the bank around the first trench, and a second cathode electrode portion disposed on a lower surface of the first trench, and
wherein the first cathode electrode portion and the second cathode electrode portion are spaced apart from each other at at least one side surface of the first trench.

5. The display device of claim 4, wherein the encapsulation layer comprises a first encapsulation layer, a second encapsulation layer on the first encapsulation layer, and a third encapsulation layer on the second encapsulation layer, and
wherein the first encapsulation layer is disposed to extend from the upper surface of the bank to the lower surface of the first trench.

6. The display device of claim 1, further comprising:
at least one inverse taper structure disposed in the first trench.

7. The display device of claim 6, wherein the cathode electrode comprises a first cathode electrode portion disposed on an upper surface of the bank around the first trench, a second cathode electrode portion disposed on at least one side surface of the first trench, and a third cathode electrode portion disposed on the at least one inverse taper structure, and
wherein the third cathode electrode portion is in an electrically floating state.

8. The display device of claim 1, wherein the bank further comprises a second trench and a third trench disposed at a predetermined interval.

9. The display device of claim 8, wherein the second trench and the third trench overlap with the at least one touch metal.

10. The display device of claim 8, wherein the cathode electrode comprises a first cathode electrode portion disposed on an upper surface of the bank around the second trench and the third trench, and a second cathode electrode portion disposed on a lower surface of each of the second and third trenches, and
wherein the first cathode electrode portion and the second cathode electrode portion are spaced apart from each other at a respective side surface of each of the second trench and the third trench.

11. The display device of claim 10, wherein the encapsulation layer comprises a first encapsulation layer, a second encapsulation layer on the first encapsulation layer, and a third encapsulation layer on the second encapsulation layer, and
wherein the first encapsulation layer is disposed to extend from the upper surface of the bank to the lower surface of each of the second trench and the third trench.

12. The display device of claim 8, further comprising:
at least one inverse taper structure disposed in at least one of the second trench and the third trench.

13. The display device of claim 12, wherein the cathode electrode comprises a first cathode electrode portion disposed on an upper surface of the bank around the second and third trenches, a second cathode electrode portion disposed on a lower surface of each of the second trench and the third trench, a third cathode electrode portion disposed on a side surface of each of the second trench and the third trench, and a fourth cathode electrode portion disposed on the at least one inverse taper structure, and
wherein the fourth cathode electrode portion is in an electrically floating state.

14. A display device comprising:
a substrate;
a bank disposed on the substrate;
a cathode electrode disposed on the bank;
an encapsulation layer disposed on the cathode electrode;
a touch insulating layer disposed on the encapsulation layer; and
a touch metal disposed on the touch insulating layer,
wherein the cathode electrode comprises an opening in at least a portion of an area overlapping with the touch metal.

15. The display device of claim 14, further comprising:
a floating metal disposed in the opening and disposed on the bank,
wherein the floating metal comprises a same material as the cathode electrode.

16. The display device of claim 15, wherein the cathode electrode and the floating metal are disposed to be spaced apart from each other on the bank,
wherein the encapsulation layer comprises a first encapsulation layer, a second encapsulation layer on the first encapsulation layer, and a third encapsulation layer on the second encapsulation layer, and
wherein the first encapsulation layer is disposed between at least one side surface of the cathode electrode and at least one side surface of the floating metal, and electrically disconnects the cathode electrode and the floating metal.

17. The display device of claim 14, wherein a width of the opening of the cathode electrode is greater than or equal to a width of the touch metal.

18. The display device of claim 14, further comprising:
an insulating layer disposed in the opening of the cathode electrode.

19. A display panel comprising:
a substrate;
a bank disposed on the substrate;
a cathode electrode disposed on the bank;
an encapsulation layer disposed on the cathode electrode;
a touch insulating layer disposed on the encapsulation layer; and
a touch metal disposed on the touch insulating layer,
wherein the encapsulation layer has a first thickness in a first area not overlapping with the touch metal, and a second thickness greater than the first thickness in a second area overlapping with the touch metal.

20. The display panel of claim 19, wherein the encapsulation layer comprises a first encapsulation layer, a second encapsulation layer on the first encapsulation layer, and a third encapsulation layer on the second encapsulation layer, and
wherein a thickness of the first encapsulation layer in the first area is the same as that of the first encapsulation layer in the second area, a thickness of the third encapsulation layer in the first area is the same as that of the third encapsulation layer in the second area, and a thickness of the second encapsulation layer in the first area is greater than that of the second encapsulation layer in the second area.
